(19) United States
(12) Patent Application Publication
(10) Pub. No.: US 2026/0063999 A1
(43) Pub. Date: Mar. 5, 2026

(54) NEGATIVE PHOTOSENSITIVE RESIN COMPOSITION, PRODUCTION METHOD FOR POLYIMIDE CURED FILM USING SAME, AND POLYIMIDE CURED FILM

(71) Applicant: ASAHI KASEI KABUSHIKI KAISHA, Tokyo (JP)

(72) Inventors: Yuka SATO, Tokyo (JP); Satoshi SHIBUI, Tokyo (JP); Takanobu FUJIOKA, Tokyo (JP)

(73) Assignee: ASAHI KASEI KABUSHIKI KAISHA, Tokyo (JP)

(21) Appl. No.: 19/119,204

(22) PCT Filed: Oct. 27, 2023
(86) PCT No.: PCT/JP2023/038944

§ 371 Date: Apr. 8, 2025

(30) Foreign Application Priority Data
Oct. 27, 2022 (JP) 2022-172504
Oct. 27, 2022 (JP) 2022-172510

(51) Int. Cl. G03F 7/038; C08G 73/12; G03F 7/028; G03F 7/075; G03F 7/40

(52) U.S. Cl. CPC G03F 7/0387; G03F 7/028; G03F 7/0751; G03F 7/40; C08G 73/127

(57) ABSTRACT

Provided is a negative photosensitive resin composition comprising: a polyimide (A) represented by formula (1) {in formula (1), A denotes a structure derived from a tetracarboxylic dianhydride, B denotes a structure derived from a diamine, and D denotes an imide structure, Z₁ and Z₂ may each be the same or different, and each denotes a monovalent organic group comprising a photopolymerizable functional group and at least one linking group selected from the group consisting of an ester bond, a urea bond, and an amide bond, and the photopolymerizable functional group is present at the end of Z₁ and/or Z₂, l and m are integers of 0 or 1 and satisfy l+m=1, n is an integer of 1-30, and p and q are each an integer of 0-2 and satisfy p+q≥1}; a solvent (B); and a photopolymerization initiator (C).

### FIELD

The present disclosure relates to: a negative photosensitive resin composition; a method of producing a polyimide cured film using the same; and a polyimide cured film.

### BACKGROUND

Conventionally, polyimide resins, polybenzoxazole resins, phenol resins, and the like, which have excellent heat resistance, electrical properties, and mechanical properties, have been used in insulating materials of electronic components as well as passivation films, surface protective films, interlayer insulating films, and the like of semiconductor devices. Among these resins, those provided in the form of photosensitive resin compositions can easily form heat-resistant relief pattern films through ring-closing treatment (imidization or benzoxazole formation) and thermal crosslinking by application, exposure, development, and curing of the respective compositions: therefore, they are characterized by enabling a substantial process reduction as compared to conventional non-photosensitive materials, and are thus used in the production of semiconductor devices.

Incidentally, semiconductor devices (hereinafter, also referred to as “elements”) are mounted on printed circuit boards by various methods in accordance with the intended purpose. Conventional elements are generally produced by a wire bonding method in which thin wires are used for connecting external terminal (pads) to a lead frame. However, today where the speed of such elements has been increased and the operating frequency has reached the GHz level, a difference in wiring length of terminals in mounting has come to affect the operation of each element. Therefore, mounting of elements for high-end application requires a precise control of the length of mounting wiring, making it difficult to satisfy this requirement by wire bonding.

In light of this, flip-chip mounting has been proposed in which a rewiring layer is formed on the surface of a semiconductor chip, bumps (electrodes) are formed thereon, and the chip is then flipped and directly mounted on a printed circuit board. This flip-chip mounting allows precise control of the wiring distance; therefore, it has been adopted to those elements for high-end applications that handle high-speed signals, or mobile phones and the like because of small mounting size, and the demand for the flip-chip mounting is rapidly expanding. Further, a semiconductor chip mounting technology called fan-out wafer-level packaging (FOWLP) has recently been proposed, in which individual chips are produced by dicing a pre-processed wafer and then reconstructed on a support and sealed with a mold resin, and this support is subsequently peeled off, followed by formation of a rewiring layer (e.g., PTL 1). In FOWLP, the rewiring layer is formed at a small thickness; therefore, FOWLP is advantageous in that it not only allows a reduction in package height, but also can increase the transmission speed and reduce the cost.

On the other hand, in FOWLP, since the rewiring layer is multilayered, there is a problem in that, in the photolithography process using a photoresist, poor flatness of a photosensitive resin composition causes a variation in the focus depth and significantly deteriorates the resolution. Therefore, the flatness of the photosensitive resin composition needs to be increased. In addition, since a copper wiring comes into contact with the rewiring layer because of the structure of the package, the photosensitive resin composition is required to be adhesive to copper.

For planarization of the rewiring layer, the in-plane uniformity of the photosensitive resin composition during spin coating (i.e. flatness during coating) and suppression of cure shrinkage during heat curing are important. The flatness of the rewiring layer (i.e. post-curing flatness) is derived from a sum of the in-plane uniformity during spin coating and the amount of cure shrinkage during heating. In order to improve the in-plane uniformity during spin coating, it is known to employ a method using a highly soluble polyimide precursor or a low-molecular-weight polymer.

For example, PTL 1 discloses a technology that can improve the in-plane uniformity during spin coating by using a low-molecular-weight polyimide precursor.

Further, PTL 2 discloses a technology for inhibiting the cure shrinkage by using a polyimide resin with a polyfunctional (meth)acrylate.

Moreover, in PTL 3, inhibition of cure shrinkage and satisfactory copper adhesion are both achieved by using a polyimide with an appropriate polyfunctional (meth)acrylate.

For example, PTL 4 discloses: a modified polyimide resin obtained by allowing a polyimide resin, which is obtained by a reaction between a tetracarboxylic acid component having an alicyclic structure and a diamine component, to react with a functional group-containing compound; and a photosensitive resin composition containing the same.

### CITATION LIST

### Patent Literature

[PTL 1] WO 2018/037997
[PTL 2] Japanese Unexamined Patent Publication (Kokai) No. 2021-152634
[PTL 3] WO 2018/154688
[PTL 4] WO 2021/140845

### SUMMARY

### Technical Problem

The use of the polyimide precursor disclosed in PTL 1 leads to a large cure shrinkage due to ring closure, and there is room for improvement in terms of flatness.

In PLT 2, an addition of the polyfunctional (meth)acrylate inhibits the interaction between a polymer and a copper interface; therefore, there is room for improvement in terms of adhesion to copper.

Further, PTL 3 offers no description with regard to the copper adhesion after a reliability test, and there is room for improvement in terms of adhesion to copper after a reliability test.

Moreover, in PTL 4, the modified polyimide resin has a high solubility, and an exposed portion of the photosensitive resin composition containing the modified polyimide resin is likely to elute into a developing liquid; therefore, there is room for improvement in terms of resolution.

In recent years, with diversification of package mounting technologies that has led to a greater variety in the types of supports and an increase in the number of rewiring layers, it is demanded to increase the flatness of insulating materials used for the formation of wiring. A polyfunctional (meth)acrylate is often used for planarizing a photosensitive resin composition; however, since it inhibits the interaction between a polymer and copper, there is a concern about deterioration of the copper adhesion after a reliability test.

An object of the present disclosure is to provide: a negative photosensitive resin composition capable of forming a cured relief pattern that has a high in-plane uniformity during spin coating, a low cure shrinkage, a high chemical resistance, a high copper adhesion, and a high resolution; a method of producing a polyimide cured film using the same; and a polyimide cured film.

### Solution to Problem

[1] A negative photosensitive resin composition, containing:
(A) a polyimide represented by the following Formula (1):

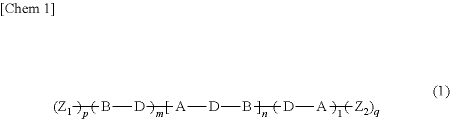

{wherein, A represents a tetracarboxylic dianhydride-derived structure; B represents a diamine-derived structure; D represents an imide structure; Z₁ and Z₂ are optionally the same or different, and each represents a monovalent organic group that contains a photopolymerizable functional group and at least one linking group selected from the group consisting of an ester bond, a urea bond, and an amide bond, which the photopolymerizable functional group exists on an end of Z₁ and/or that of Z₂; l and m each represent an integer of 0 or 1, satisfying l+m=1; n represents an integer of 1 to 30; and p and q each represent an integer of 0 to 2, satisfying p+q≥1};
(B) a solvent; and
(C) a photopolymerization initiator.

[2] The negative photosensitive resin composition according to [1], wherein the amount of an alicyclic structure contained in the polyimide (A) is 1% by mole to 45% by mole.

[3] The negative photosensitive resin composition according to [1] or [2], wherein Z₁ and Z₂ are each a monovalent organic group that contains a linking group of an ester bond and a photopolymerizable functional group.

[4] The negative photosensitive resin composition according to [1] or [2], wherein Z₁ and Z₂ are each a monovalent organic group that contains a linking group of a urea bond and a photopolymerizable functional group.

[5] The negative photosensitive resin composition according to any one of [1] to [4], wherein the polyimide (A) has a molecular weight distribution (Mw/Mn) of 1.0 to 1.8.

[6] The negative photosensitive resin composition according to any one of [1] to [5], wherein the polyimide (A) has a weight-average molecular weight (Mw) of 3,000 to 25,000.

[7] The negative photosensitive resin composition according to any one of [1] to [6], further containing a polymerizable functional group-containing monomer (D).

[8] The negative photosensitive resin composition according to [7], wherein the polymerizable functional group-containing monomer (D) contains a monofunctional monomer (D1) and a polyfunctional monomer (D2).

[9] The negative photosensitive resin composition according to [8], wherein a weight ratio of the D1 and the D2 is 0.01<D1/D2≤1.

[10] The negative photosensitive resin composition according to any one of [1] to [9], further containing a silane coupling agent (E).

[11] The negative photosensitive resin composition according to any one of [1] to [10], further containing an organic titanium compound (F).

[12] The negative photosensitive resin composition according to any one of [1] to [11], further containing a thermal crosslinking agent (G).

[13] The negative photosensitive resin composition according to any one of [1] to [12], further containing a rust inhibitor (H).

[14] The negative photosensitive resin composition according to any one of [1] to [13], further containing a thermal polymerization initiator (I).

[15] The negative photosensitive resin composition according to any one of [1] to [14], further containing a plasticizer (J).

[16] The negative photosensitive resin composition according to any one of [1] to [3] and [5] to [16], wherein the structures represented by Z₁ and Z₂ in the Formula (1) are represented by the following Formula (27):

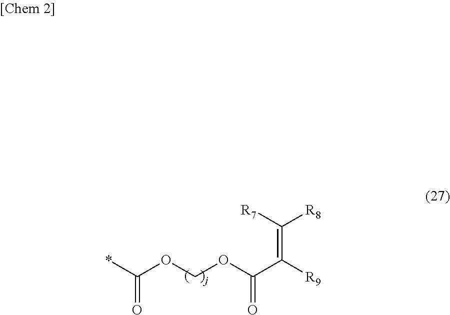

(wherein, R₇, R₈, and R₉ each independently represent a hydrogen atom or a monovalent organic group having 1 to 3 carbon atoms; j represents an integer of 2 to 10; and * represents a binding site with an end of the polyimide (A)).

[18] The negative photosensitive resin composition according to any one of [1], [2], and [4] to [15], wherein the structures represented by Z₁ and Z₂ in the Formula (1) are represented by the following Formula (25):

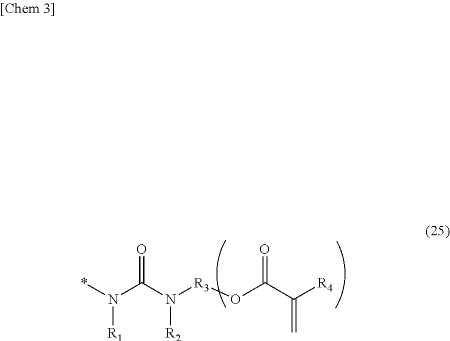

(wherein, R₁ and R₂ are each independently selected from a hydrogen atom and a monovalent organic group having 1 to 3 carbon atoms; R₃ represents an organic group having l to 20 carbon atoms, which optionally contains a heteroatom; k represents an integer of 1 or 2; R₄ represents a hydrogen atom or an organic group having 1 to 4 carbon atoms; and * represents a binding site with an end of the polyimide (A)).

[18] The negative photosensitive resin composition according to any one of [1], [2], [4] to [15], and [17], wherein the structures represented by Z₁ and Z₂ in the Formula (1) are each at least one selected from the group consisting of the following Formulae (28) to (31):

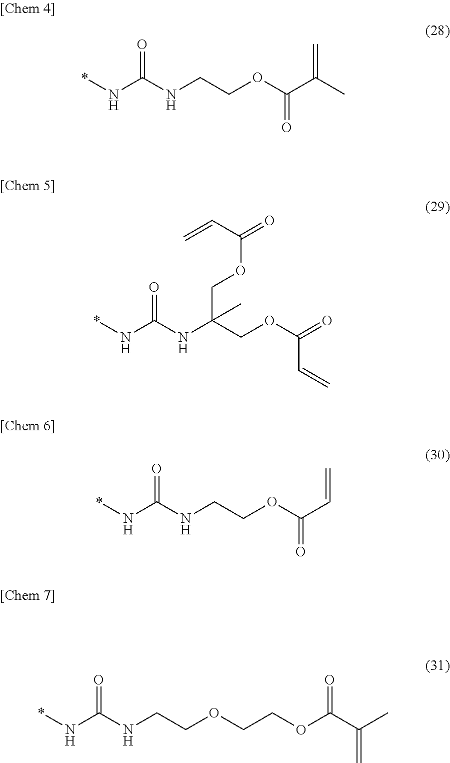 [SMILES: *NC(=O)NCCOC(=O)C(=C)C ; *NC(=O)NC(C)(COC(=O)C=C)COC(=O)C=C ; *NC(=O)NCCOC(=O)C=C ; *NC(=O)NCCOCCOC(=O)C(=C)C]

{wherein, “*” is a binding site with an end of the polyimide (A)}.

[19] The negative photosensitive resin composition according to any one of [1] to [19], wherein A in the Formula (1) has at least one or more of the structures represented by the following Formulae (2) to (9):

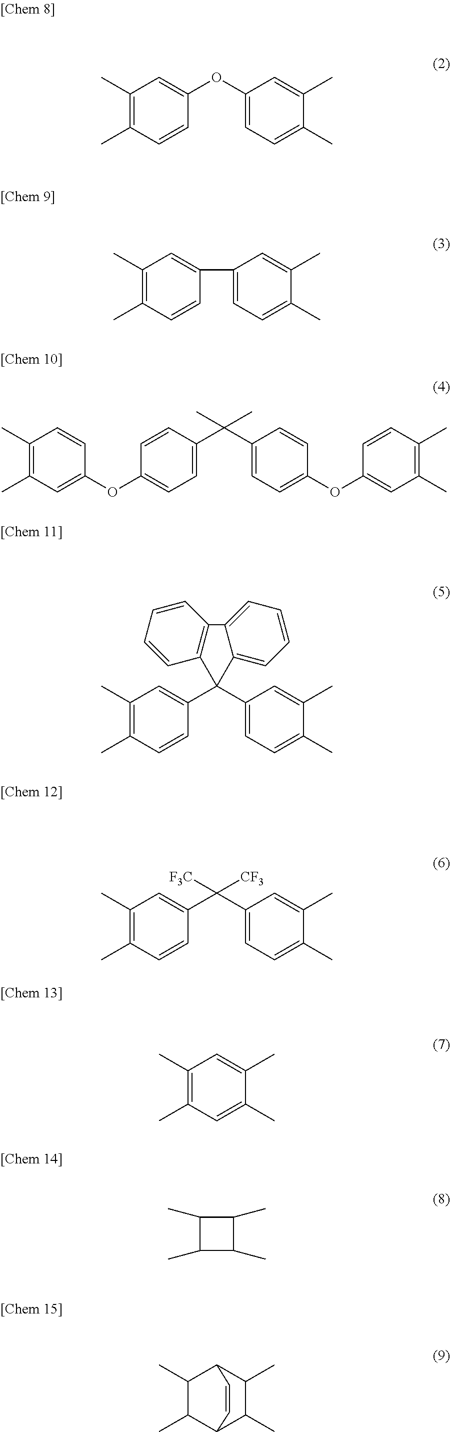

[20] The negative photosensitive resin composition according to any one of [1] to [19], wherein A in the Formula (1) has at least one or more of the structures represented by the following Formulae (8) and (9):

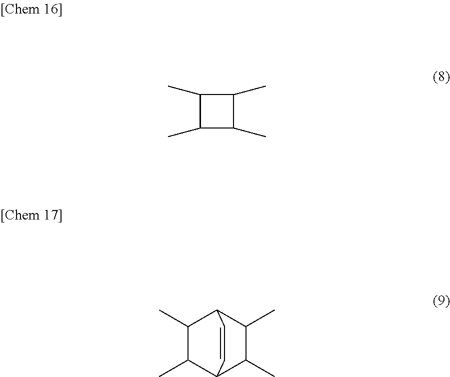

[21] The negative photosensitive resin composition according to any one of [1] to [19], wherein B in the Formula (1) has at least one or more of the structures represented by the following Formulae (10) to (21):

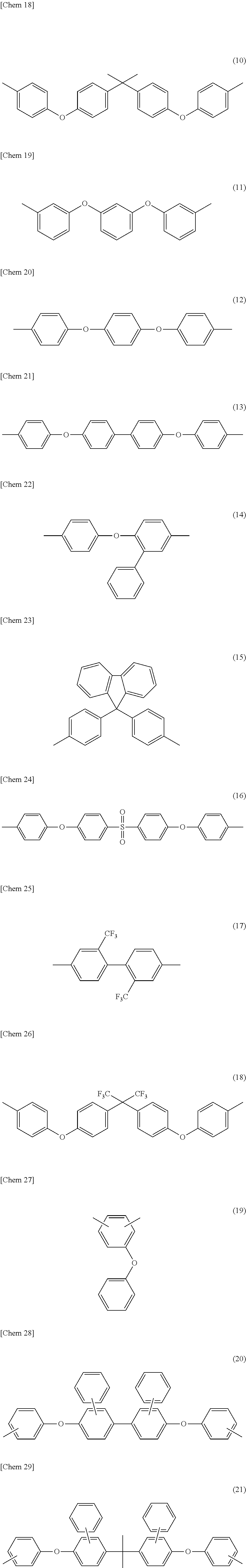

[22] The negative photosensitive resin composition according to any one of [1] to [22], wherein B in the Formula (1) has at least one or more of the structures represented by the following Formulae (14), (19), (20), and (21):

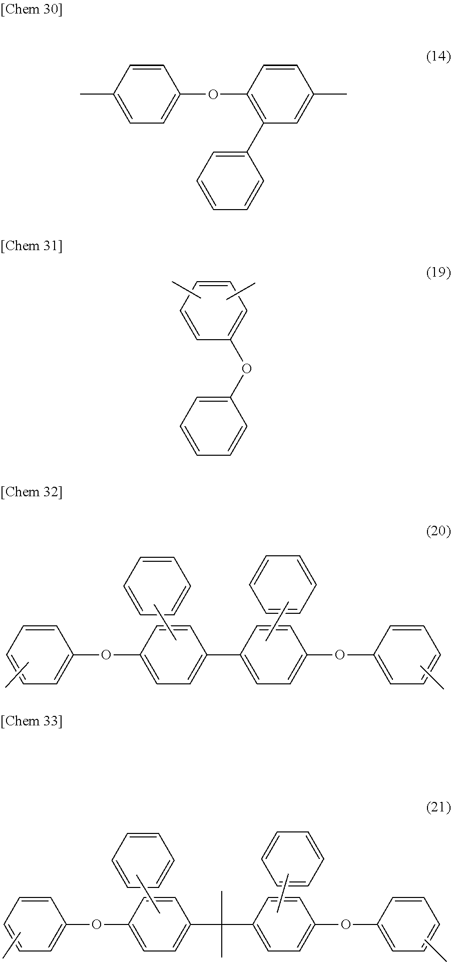

[13] A negative photosensitive resin composition, containing:
(A) a polyimide represented by the following Formula (1):

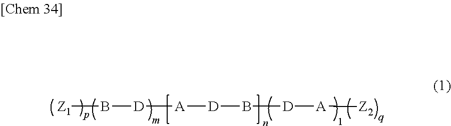

{wherein, A represents a tetracarboxylic dianhydride-derived structure; B represents a diamine-derived structure; D represents an imide structure; Z₁ and Z₂ are optionally the same or different, and each represent a monovalent organic group that contains a photopolymerizable functional group and at least one linking group selected from the group consisting of an ester bond, a urea bond, and an amide bond, which the photopolymerizable functional group exists on an end of Z₁ and/or that of Z₂; l and m each represent an integer of 0 or 1, satisfying l+m=1; n represents an integer of 1 to 30; and p and q each represent an integer of 0 to 2, satisfying p+q≥1};
(B) a solvent; and
(C) a photopolymerization initiator, wherein the negative photosensitive resin composition satisfies the following Equation (I):

$$[ Math 1 ]$$

$$80 < \frac{Im}{Fc \times ( Mw / Mn )} \qquad ( I )$$

{wherein, Im represents an imidization rate; Fc represents a post-curing flatness; and Mw/Mn represents a molecular weight distribution of the polyimide (A)}.

[24] A polyimide cured film, obtained by curing the negative photosensitive resin composition according to any one of [1] to [23].

[25] A method of producing a cured relief pattern, the method including:
(1) the step of applying the negative photosensitive resin composition according to any one of [1] to onto a substrate to form a photosensitive resin layer on the substrate;
(2) the step of exposing the photosensitive resin layer;
(3) the step of developing the exposed photosensitive resin layer to form a relief pattern; and
(4) the step of heat-treating the relief pattern to form a cured relief pattern.

[26] A method of producing a polyimide having a photopolymerizable functional group on a main chain end, the method including:
the step of dehydrating and ring-closing a polyamic acid, which is obtained by reacting a tetracarboxylic dianhydride with a diamine, by a heat treatment to obtain a polyimide having a reactive group on the main chain end; and
the step of reacting the polyimide having a reactive group on the main chain end with a compound having a photopolymerizable functional group on an end,
wherein the compound having a photopolymerizable functional group on an end is at least one type compound selected from the group consisting of isocyanate compounds, chloride compounds, and alcohol compounds.

[27] The method of producing a polyimide according to [26], wherein
the reactive group is a carboxyl group, and
the compound having a photopolymerizable functional group on an end is an alcohol compound.

[28] The method of producing a polyimide according to [26], wherein
the reactive group is an amino group, and
the compound having a photopolymerizable functional group on an end is at least one type compound selected from the group consisting of isocyanate compounds and chloride compounds.

[29] A method of producing a negative photosensitive resin composition, the method including:
the step of producing a polyimide (A) by the method according to any one of to [28]; and
the step of mixing 100 parts by mass of the polyimide (A) with 30 to 1,000 parts by mass of a solvent (B) and 1 to 30 parts by mass of a photopolymerization initiator (C) to obtain a negative photosensitive resin composition.

In more details, the present invention is as described below.

### Advantageous Effects of Invention

According to the present disclosure, the following can be provided: a photosensitive resin composition capable of forming a cured relief pattern that exhibits a high in-plane uniformity during spin coating, a low cure shrinkage, and good copper adhesion; a method of producing a polyimide cured film using the same; and a polyimide cured film.

### DESCRIPTION OF EMBODIMENTS

Embodiments of the present disclosure will now be described in detail. Throughout the present disclosure, when there are plural structures in a molecule, unless otherwise specified, those structures denoted by the same symbol in a general formula are each independently selected and may be the same or different from each other.

Further, unless otherwise specified, those structures denoted by a common symbol in different general formulae are also each independently selected and may be the same or different from each other.

### <Negative Photosensitive Resin Composition>

The negative photosensitive resin composition of the present disclosure (hereinafter, referred to as “photosensitive resin composition”) contains a specific polyimide (A), a solvent (B), and a photopolymerization initiator (C). In addition to these components, as desired, the negative photosensitive resin composition of the present disclosure may further contain additives selected from the group consisting of a polymerizable functional group-containing monomer (D) (a radical polymerizable compound in one mode), a silane coupling agent (E), an organic titanium compound (F), a thermal crosslinking agent (G), a rust inhibitor (H), a thermal polymerization initiator (I), and a plasticizer (J), as well as other components.

### Polyimide (A)

The negative photosensitive resin composition of the present disclosure contains a polyimide (A) represented by the following Formula (1):

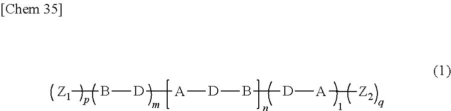

{wherein, A represents a tetracarboxylic dianhydride-derived structure; B represents a diamine-derived structure; D represents an imide structure; Z₁ and Z₂ are optionally the same or different, and each represent a monovalent organic group that contains a photopolymerizable functional group and at least one linking group selected from the group consisting of an ester bond, a urea bond, and an amide bond, which photopolymerizable functional group exists on an end of Z₁ and/or that of Z₂; land m each represent an integer of 0 or 1, satisfying l+m=1; n represents an integer of 1 to 30; and p and q each represent an integer of 0 to 2, satisfying p+q≥1}.

The term “organic group” used herein means a group having at least one carbon atom.

The polyimide used in the present disclosure is synthesized from a tetracarboxylic dianhydride and a diamine. In Formula (1), A represents a tetracarboxylic dianhydride-derived structure, and B represents a diamine-derived structure.

The structure of A is not particularly limited as long as it is a known tetracarboxylic dianhydride-derived structure; however, from the standpoint of the solubility in the solvent (B), A preferably has at least one of the structures represented by the following Formulae (2) to (9):

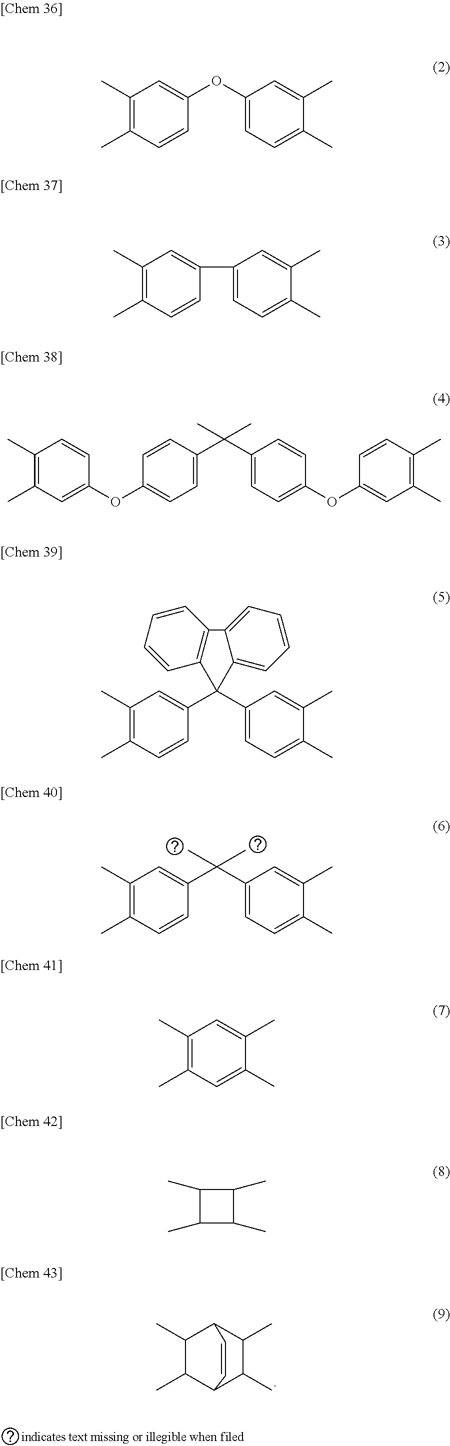

Further, from the standpoint of the chemical resistance of a cured film obtained from the negative photosensitive resin composition of the present disclosure, A preferably has at least one of the structures represented by Formulae (2) to (9).

From the standpoint of the heat resistance of a cured film obtained from the negative photosensitive resin composition of the present disclosure, A more preferably has at least one of the structures represented by Formulae (2), (3), (5), and (7) to (9).

From the standpoint of the resolution of the negative photosensitive resin composition of the present disclosure, A preferably has at least one of the structures represented by Formulae (8) and (9).

In Formula (1), B represents a diamine-derived structure. The structure of B is not particularly limited as long as it is a known diamine-derived structure; however, from the standpoint of the solubility in the solvent (B), B preferably has at least one of the structures represented by the following Formulae (10) to (21):

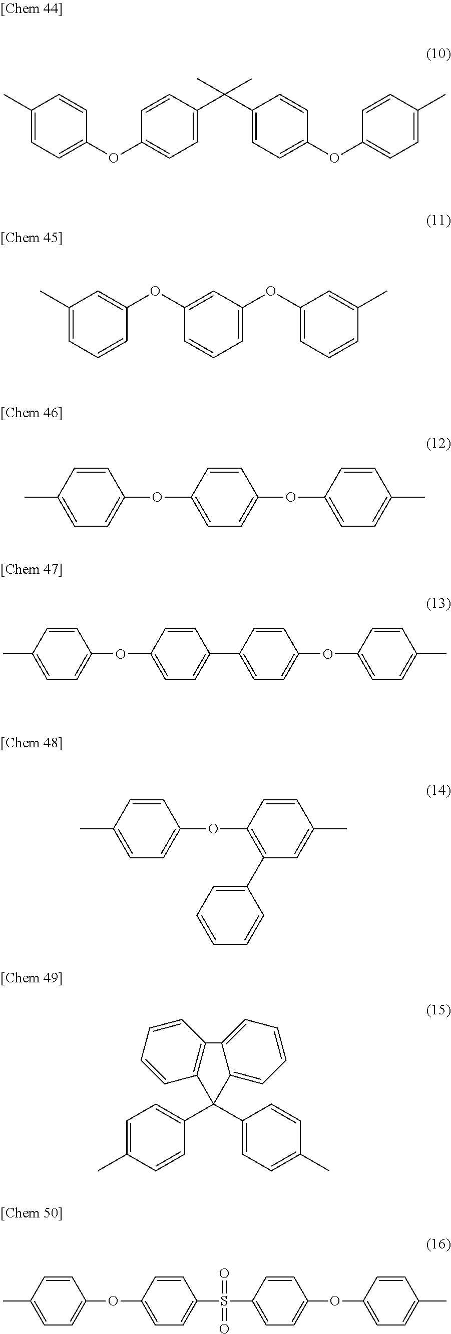

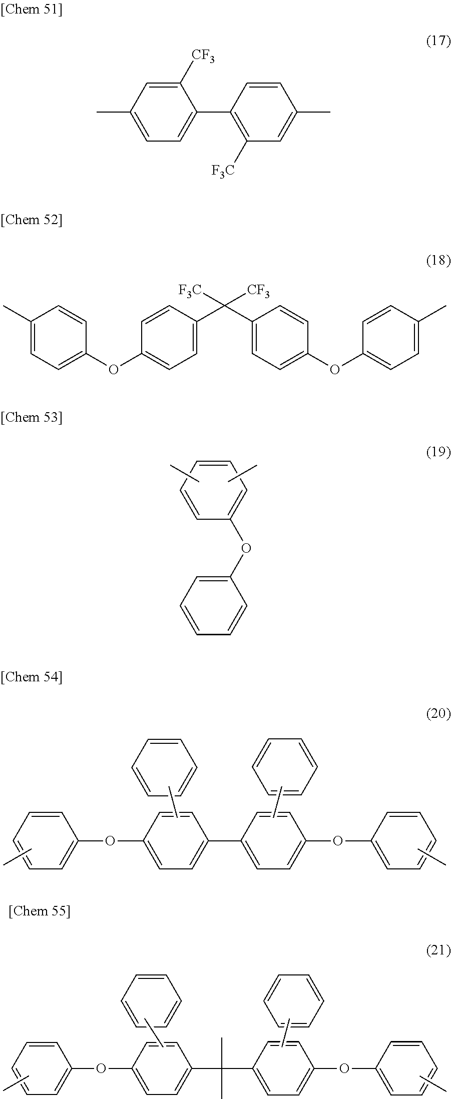

Further, from the standpoint of the chemical resistance of a cured film obtained from the negative photosensitive resin composition of the present disclosure, B preferably has at least one of the structures represented by Formulae (10) to (21).

From the standpoint of the mechanical properties of a cured film obtained from the negative photosensitive resin composition of the present disclosure, B more preferably has at least one of the structures represented by Formulae (12), (14), (15), and (19) to (21).

From the standpoint of the in-plane uniformity of a cured film obtained from the negative photosensitive resin composition of the present disclosure, B preferably has at least one of the structures represented by Formulae (15), and (19) to (21).

From the standpoint of the resolution of the negative photosensitive resin composition of the present disclosure, the polyimide (A) of the present disclosure preferably contains an alicyclic structure. The alicyclic structure is a structure derived from a tetracarboxylic dianhydride or a diamine.

The alicyclic structure of the present disclosure refers to a non-aromatic structure in which three or more carbon atoms are bound to form a ring. The alicyclic structure of the present disclosure is a structure in which three or more carbon atoms are bound to form a ring, and has preferably 4 to 20 carbon atoms, more preferably 6 to 10 carbon atoms.

Specific examples of the alicyclic structure of the present disclosure include: cycloalkane structures, such as cyclopropane, cyclobutane, cyclopentane, cyclohexane, cycloheptane, and cyclooctane; chair structures, such as bicyclooctane and bicyclooctene; and structures represented by the following Formulae (22) to (24):

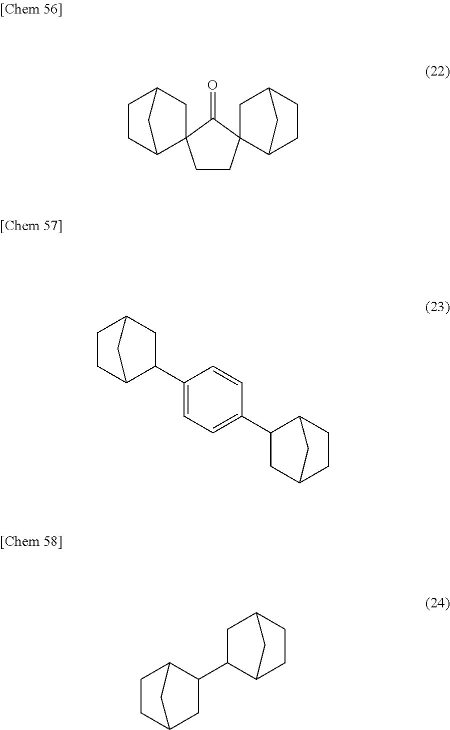

From the standpoint of the physical properties of a cured film, the alicyclic structure contained in the polyimide (A) is preferably a cycloalkane structure or a chair structure, and the chair structure is preferably bicyclooctane, bicyclooctene, or the like.

From the standpoint of the solubility of the polyimide (A) in the solvent (B) and the resolution of the negative photosensitive resin composition of the present disclosure, the content of the alicyclic structure in the polyimide (A) is preferably 1% by mole to 45% by mole. A lower limit value of the content is more preferably 5% by mole, still more preferably 10% by mole, particularly preferably 15% by mole. An upper limit value of the content is more preferably 40% by mole, still more preferably 35% by mole, particularly preferably 30% by mole.

The content ratio of the alicyclic structure in the polyimide (A) can be calculated by dividing the added molar amount of alicyclic structure-containing tetracarboxylic dianhydride and/or diamine among those tetracarboxylic dianhydrides and diamines that are used for the synthesis of the polyimide (A) by a total molar amount of the tetracarboxylic dianhydrides and the diamines.

In Formula (1), D represents an imide structure generated by a reaction between a tetracarboxylic dianhydride and a diamine.

In Formula (1), Z₁ and Z₂ each represent a monovalent organic group that contains a photopolymerizable functional group and at least one linking group selected from the group consisting of an ester bond, a urea bond, and an amide bond, and the photopolymerizable functional group exists on an end of Z₁ and/or that of Z₂. Further, Z₁ and Z₂ are optionally the same or different.

Z₁ and Z₂ are each preferably a monovalent organic group that contains a photopolymerizable functional group and at least one linking group selected from the group consisting of an ester bond, a urea bond, and an amide bond, more preferably a monovalent organic group that contains a photopolymerizable functional group and at least one linking group selected from the group consisting of an ester bond and a urea bond.

The photosensitive resin composition of the present disclosure exhibits excellent resolution by containing a photopolymerizable functional group in Z₁ and Z₂.

In one mode, the photopolymerizable functional group is a radical polymerizable functional group, typically a carbon-carbon double bond moiety.

The photopolymerizable functional group of the present disclosure preferably exists on an end of Z₁ and/or that of Z₂.

The phrase “the photopolymerizable functional group of the present disclosure exists on an end of Z₁ and/or that of Z₂” means that the photopolymerizable functional group is connected to A and B in the polyimide (A) of the present disclosure via a linking group.

The urea bond of the present disclosure represents the following structure.

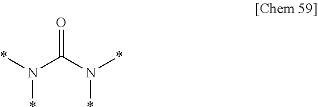 [SMILES: *N(*)C(=O)N(*)*]

(wherein, * represents a binding site with other atom).

When the linking group is an ester bond, a urea bond, or an amide bond, not only the linking group is unlikely to be thermally decomposed but also the heat resistance of the polyimide (A) and that of a cured film of the negative photosensitive resin composition containing the polyimide (A) are improved, which is preferred. From the standpoint of the copper adhesion and the resolution, the linking group is preferably a urea bond or an ester bond.

When the linking group is a urethane bond, decomposition thereof advances with heating, and the heat resistance and the post-curing flatness of a cured film of the negative photosensitive resin composition tend to be deteriorated.

Specific examples of Z₁ and Z₂ include the structures represented by the following Formulae (25) to (27).

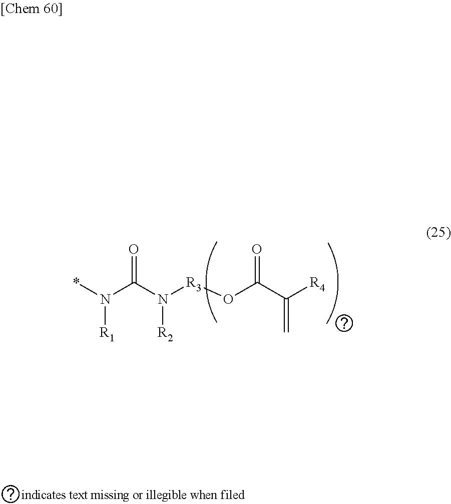

(wherein, R₁ and R₂ are each independently selected from a hydrogen atom and a monovalent organic group having 1 to 3 carbon atoms; R₃ represents an organic group having 1 to 20 carbon atoms, which optionally contains a heteroatom; k represents an integer of 1 or 2; R₄ represents a hydrogen atom or an organic group having 1 to 4 carbon atoms; and * represents a binding site with an end of the polyimide (A))

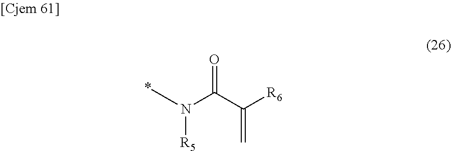

(wherein, R₅ and R₆ each independently represent a hydrogen atom and a monovalent organic group having 1 to 3 carbon atoms; and * represents a binding site with an end of the polyimide (A))

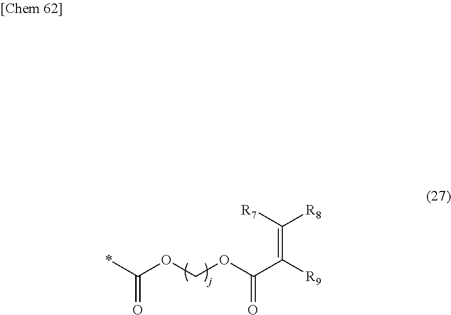

(wherein, R₇, R₈, and R₉ each independently represent a hydrogen atom or a monovalent organic group having 1 to 3 carbon atoms; j represents an integer of 2 to 10; and * represents a binding site with an end of the polyimide (A))

More detailed specific examples of the structure represented by Formula (25) include the structures represented by the following Formulae (28) to (31):

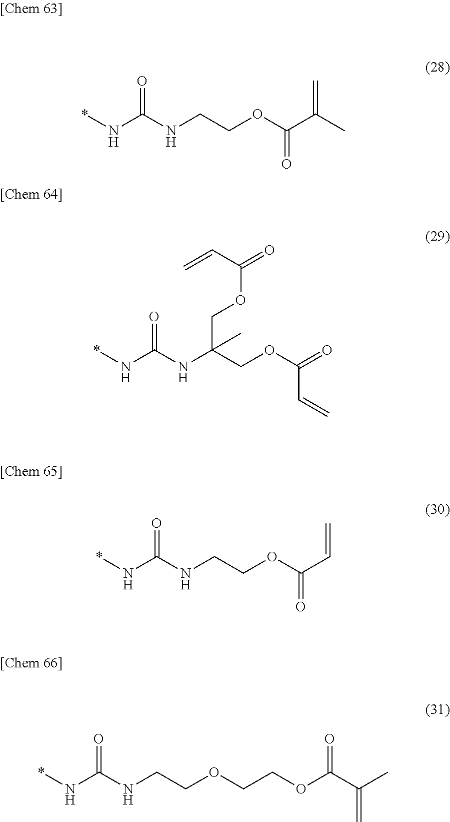 [SMILES: *NC(=O)NCCOC(=O)C(=C)C ; *NC(=O)NC(C)(COC(=O)C=C)COC(=O)C=C ; *NC(=O)NCCOC(=O)C=C ; *NC(=O)NCCOCCOC(=O)C(=C)C]

(wherein, * represents a binding site with an end of the polyimide (A))

More detailed specific examples of the structure represented by Formula (26) include the structures represented by the following Formulae (32) and (33):

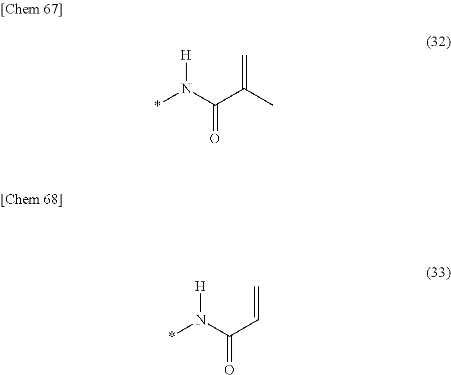

(wherein, * represents a binding site with an end of the polyimide (A))

More detailed specific examples of the structure represented by Formula (27) include the structures represented by the following Formulae (34) to (37):

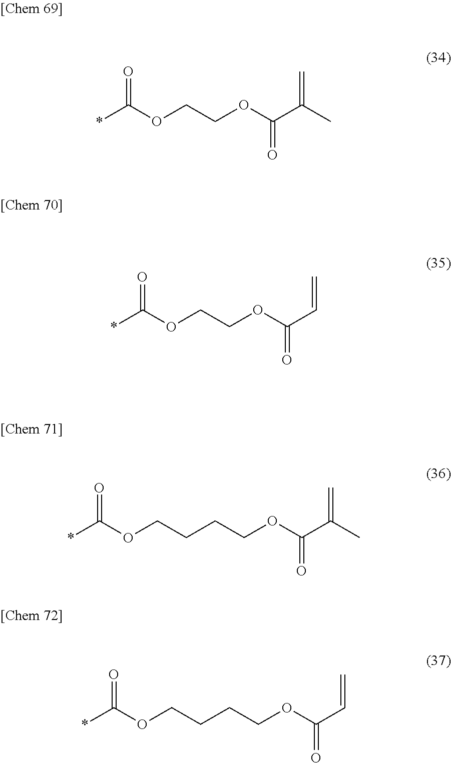 [SMILES: *C(=O)OCCOC(=O)C(=C)C ; *C(=O)OCCOC(=O)C=C ; *C(=O)OCCCCOC(=O)C(=C)C ; *C(=O)OCCCCOC(=O)C=C]

(wherein, * represents a binding site with an end of the polyimide (A))

From the standpoint of the resolution, the modification rate of the ends of the polyimide (A) (in one mode, the modification rate of Z₁ and Z₂ with respect to the polyimide main chain) is preferably 90% or more, more preferably 95% or more.

In Formula (1), 1 and m each represent an integer of 0 or 1, satisfying l+m=1;
n represents an integer of 1 to 30, which is an integer satisfying the weight-average molecular weight of the polyimide (A); and
p and q each represent an integer of 0 to 2, satisfying p+q≥1.

The weight-average molecular weight (Mw) of the polyimide (A) is not particularly limited as long as it is in a range where the polyimide (A) is dissolved in the solvent (B); however, it is preferably 3,000 to 25,000 from the standpoint of the mechanical properties and the copper adhesion of a cured film obtained from the negative photosensitive resin composition of the present disclosure. A lower limit value of the weight-average molecular weight of the polyimide (A) is more preferably 4,000 or more, still more preferably 5,000 or more. Further, from the standpoint of the solubility in the solvent (B), the resolution, and the in-plane uniformity during coating (particularly the cured flatness), an upper limit value of the weight-average molecular weight of the polyimide (A) is more preferably 23,000 or less, particularly preferably 20,000 or less.

The polyimide (A) preferably has a molecular weight distribution (Mw/Mn) of 1.0 to 1.8. From the standpoint of the resolution and the production efficiency, the molecular weight distribution (Mw/Mn) is more preferably 1.15 to 1.8, still more preferably 1.25 to 1.8.

From the standpoint of the post-curing flatness, the imidization rate (Im) of the polyimide (A) is preferably 90% or more, more preferably 95% or more. It is noted here that an upper limit of Im is 100%.

The imidization rate (Im) of the present disclosure represents a ratio of amide bonds in a polyamic acid, which is a precursor of the polyimide, that is converted to imide bonds by dehydration and ring closure.

The imidization rate (Im) of the polyimide (A) is measured by the method described below in the section of Examples.

### <Method of Producing Polyimide Having Photopolymerizable Functional Group on Main Chain End>

A method of producing the polyimide (A) includes:
the step of dehydrating and ring-dosing a polyamic acid, which is obtained by reacting a tetracarboxylic dianhydride with a diamine, by a heat treatment to obtain a polyimide having a reactive group on a main chain end (in one mode, an end); and
the step of reacting the polyimide having a reactive group on a main chain end with a compound having a photopolymerizable functional group on an end.

The term “reactive group” used herein means a tetracarboxylic dianhydride-derived carboxyl group or acid anhydride group of a polyimide end, or a diamine-derived amino group derived.

The method of producing a polyimide according to the present disclosure can produce a polyimide having a photopolymerizable functional group on a main chain end. In other words, the method of producing a polyimide according to the present disclosure can produce a polyimide having a modified main chain end.

Specific examples of the tetracarboxylic dianhydride include, but not particularly limited to, 4,4′-oxydiphthalic anhydride (ODPA), 3,3′,4,4′-biphenyltetracarboxylic dianhydride, 4,4′-(4,4′-isopropylidenediphenoxy)diphthalic anhydride (BPADA), 9,9-bis(3,4-dicarboxyphenyl)fluorene dianhydride, 4,4′-(hexafluoroisopropylidene)diphthalic anhydride, norbomane-2-spiro-α-cyclopentanone-α′-spiro-2″-norbomane-5,5″,6,6″-tetracarboxylic dianhydride (CpODA), bicyclo[2.2.2]oct-7-ene-2,3,5,6-tetracarboxylic dianhydride (BCD), and 1,2,3,4-cyclobutanetetracarboxylic anhydride (CBDA).

Specific examples of the diamine include, but not particularly limited to, 2,2-bis[4-(4-aminophenoxy)phenyl]propane, 1,3-bis(3-aminophenoxy)benzene (APB), 1,4-bis(4-aminophenoxy)benzene (TPE-Q), 6-(4-aminophenoxy)[1,1′-biphenyl]-3-amine (PDPE), 4,4′-bis(4-aminophenoxy)biphenyl, bis[4-(3-aminophenoxy)phenyl]sulfone, bis[4-(4-aminophenoxy)phenyl]sulfone (BAPS), 9,9-bis(4-aminophenyl)fluorene (BAFL), 2,2′-dimethylbenzidine, 2,2′-bis(trifluoromethyl)benzidine (TFMB), 2,2-bis[4-(4-aminophenoxy)phenyl]hexafluoropropane (HFBAPP), 2,2′-dimethylbiphenyl-4,4′-diamine (m-tolidine), 3,3′-diphenyl-4,4′-bis(4-aminophenoxy)biphenyl (APBP-DP), and 2,2-bis[3-phenyl-4-(4-aminophenoxy)phenyl]propane (DAOPPA).

The compound having a photopolymerizable functional group on an end is preferably at least one compound selected from the group consisting of isocyanate compounds, chloride compounds, and alcohol compounds.

Specific examples of the compound having a photopolymerizable functional group on an end include:
isocyanate compounds, such as 2-methacryloyloxyethyl isocyanate (product name: KARENZ MOI, manufactured by Showa Denko K.K), 2-acryloyloxyethyl isocyanate (product name: KARENZ MOI, manufactured by ShowaDenko K.K.), 1,1-(bisacryloyloxymethyl)ethyl isocyanate (product name: KARENZ AOI, manufactured by Showa Denko K.K.), and 2-(2-methacryloyloxyethyloxy)ethyl isocyanate (product name: KARENZ MOI-EG, manufactured by Showa Denko K.K.);
chloride compounds, such as acryloyl chloride and methacryloyl chloride; and
alcohol compounds, such as 2-hydroxyethyl methacrylate (HEMA), 2-hydroxyethyl acrylate, 4-hydroxyethyl methacrylate, and 4-hydroxyethyl acrylate.

An isocyanate compound reacts with an amino group of a dehydrated and ring-closed polyimide to form a urea bond.

A chloride compound reacts with an amino group of a dehydrated and ring-closed polyimide to form an amide bond.

An alcohol compound reacts with a carboxyl group of a dehydrated and ring-closed polyimide to form an ester bond.

A method of reacting an isocyanate compound is not particularly limited, and the isocyanate compound can be reacted with an amino group of a dehydrated and ring-closed polyimide by stirring at room temperature.

A method of reacting a chloride compound is not particularly limited, and the chloride compound can be added dropwise to an ice-cold solution of a dehydrated and ring-closed polyimide and thereby reacted with an amino group of the dehydrated and ring-closed polyimide.

A method of reacting an alcohol compound is not particularly limited, and the alcohol compound can be reacted with a carboxyl group of a dehydrated and ring-closed polyimide using a condensation agent such as NN-dicyclohexylcarbodiimide (DCC), or an esterification catalyst such as p-toluenesulfonic acid.

The temperature at which the polyamic acid is dehydrated and ring-closed by a heat treatment to obtain a polyimide is not particularly limited; however, since the ring-dosing reaction is not completed at a low temperature, a lower limit value of the temperature is preferably 150° C. or higher, more preferably 160° C. or higher. On the other hand, since a high temperature causes a side reaction to proceed, an upper limit value of the temperature is preferably 200° C. or lower, more preferably 180° C.

In the production of the polyimide (A), a reaction solvent may be used so as to efficiently perform the reaction in a uniform system. The reaction solvent is not particularly limited as long as it can uniformly dissolve or suspend the tetracarboxylic dianhydride, the diamine, and the compound having a photopolymerizable functional group on an end, and examples of the reaction solvent include 7-butyrolactone (GBL), dimethyl sulfoxide (DMSO), N,N-dimethylacetoacetamide, 1,3-dimethyl-2-imidazolidinone, 3-methoxy-N,N-dimethylpropanamide, 3-butoxy-N,N-dimethylpropanamide, N,N-dimethylformamide, N-methyl-2-pyrrolidone (NMP), N-ethyl-2-pyrrolidone, and N,N-dimethylacetamide.

The polyimide (A) may be purified by a known method described in Japanese Unexamined Patent Publication (Kokai) No. 2012-194520 or the like. For example, a method of dropping a polyimide (A) solution into water to cause reprecipitation and subsequently removing unreacted material, a method of separating the polyimide (A) by filtration and removing the condensation agent and the like that are insoluble in the reaction solvent, or a method of removing the catalyst with an ion exchange resin may be employed. After the purification, the polyimide (A) may be dried by a known method and isolated in a powder state.

In the negative photosensitive resin composition of the present disclosure, the polyimide (A) is contained in an amount of, for example, 35% by mass. In the negative photosensitive resin composition of the present disclosure, the polyimide (A) is contained in an amount of preferably 20 to 70% by mass, more preferably 25 to 65% by mass.

### (B) Solvent

The solvent (B) is not limited as long as it is a solvent that can uniformly dissolve or suspend the polyimide (A) and the photopolymerization initiator (C). Examples of such a solvent include γ-butyrolactone (GBL), dimethyl sulfoxide (DMSO), tetrahydrofurfuryl alcohol, ethyl acetoacetate, N,N-dimethylacetoacetamide, ε-caprolactone, 1,3-dimethyl-2-imidazolidinone, 3-methoxy-N,N-dimethylpropanamide, 3-butoxy-N,N-dimethylpropanamide, N,N-dimethylformamide, N-methyl-2-pyrrolidone, N-ethyl-2-pyrrolidone, N,N-dimethylacetamide, and ethyl lactate. These solvents may be used singly, or in combination of two or more kinds thereof.

The solvent (B) can be used in accordance with the desired coating thickness and viscosity of the negative photosensitive resin composition. The solvent (B) can be used in a range of, for example, 30 to 1,000 parts by mass, preferably 140 to 1,000 parts by mass, with respect to 100 parts by mass of the polyimide (A).

When the solvent (B) contains an alcohol having no olefinic double bond, the content of the alcohol having no olefinic double bond in the whole solvent is preferably 5 to 50% by mass. From the standpoint of the storage stability of the negative photosensitive resin composition, an upper limit value of the content is more preferably 10% by mass or more. From the standpoint of the solubility of the polyimide (A), a lower limit value of the content is more preferably 30% by mass or less.

### (C) Photopolymerization Initiator

The photopolymerization initiator (C) is a compound that is capable of generating radicals with active light and polymerizing an ethylenically unsaturated group-containing compound and the like. Examples of an initiator that generates radicals with active light include compounds containing the structures of benzophenone, N-alkylaminoacetophenone, oxime ester, acridine, phosphine oxide, lophine, and the like.

Examples of the photopolymerization initiator (C) include, but not limited to:
aromatic ketones, such as benzophenone, N,N,N′,N′-tetramethyl-4,4′-diaminobenzophenone (Michler's ketone), N,N,N′,N′-tetraethyl-4,4′-diaminobenzophenone, 4-methoxy-4′-dimethylaminobenzophenone, 2-benzyl-2-dimethylamino-1-(4-morpholinophenyl)-butanone-1,2-methyl-1-[4-(methylthio)phenyl]-2-morpholino-propanone-1, acrylated benzophenone, and 4-benzoyl-4′-methyldiphenyl sulfide;
benzoin ether compounds, such as benzoin methyl ether, benzoin ethyl ether, and benzoin phenyl ether;
benzoin compounds, such as benzoin, methyl benzoin, and ethyl benzoin;
oxime ester compounds, such as 1,2-octanedione,1-[4-(phenylthio)-2-(O-benzoyloxime)], ethanone,1-[9-ethyl-6-(2-methylbenzoyl)-9H-carbazol-3-yl]-1-(O-acetyloxime) (IRGACURE OXE02, manufactured by BASF Japan Ltd.), 1-[4-(phenylthio)phenyl]-3-cyclopentylpropane-1,2-dione-2-(o-benzoyloxime) (trade name: PBG305, manufactured by Changzhou Tronly New Electronic Materials Co., Ltd.), 1-(6-O-methylbenzoyl-9-ethylcarbazol-3-yl)-(3-cyclopentylacetone)-1-oxime acetate (trade name: TR-PBG-304, manufactured by Changzhou Tronly New Electronic Materials Co., Ltd.), TR-PBG-3057 (trade name, manufactured by Changzhou Tronly New Electronic Materials Co., Ltd.), 1,2-propanedione,3-cyclohexyl-1-[9-ethyl-6-(2-furanylcarbonyl)-9H-carbazol-3-yl]-,2-(O-acetyloxime) (trade name: TR-PBG-326, manufactured by Nikko Chemtech Co., Ltd.), and NCI-831 (trade name, manufactured by ADEKA Corporation);
benzyl derivatives, such as benzyl dimethyl ketal;
acridine derivatives, such as 9-phenylacridine and 1,7-bis(9,9′-acridinyl)heptane;
N-phenylglycine derivatives, such as N-phenylglycine;
coumarin compounds;
oxazole compounds;
phosphine oxide compounds, such as diphenyl(2,4,6-trimethylbenzoyl)phosphine oxide; and
lophine compounds, such as 2,2′-bis(2-chlorophenyl)-4,4′,5,5′-tetraphenyl-1,2′-biimidazole.

The above-exemplified photopolymerization initiators (C) may be used singly, or in combination of two or more kinds thereof. Among the above-exemplified photopolymerization initiators (C), oxime ester compounds are more preferred particularly from the standpoint of the resolution.

The content of the photopolymerization initiator (C) is preferably 1 part by mass to 30 parts by mass with respect to 100 parts by mass of the polyimide (A). From the standpoint of the photocurability, a lower limit value of the content is more preferably 4 parts by mass or more. From the standpoint of the bottom curing of a relief pattern, an upper limit value of the content is more preferably 20 parts by mass or less.

### (D) Polymerizable Functional Group-Containing Monomer

For the purposes of improving the resolution of a cured relief pattern and inhibiting the cure shrinkage during heat curing, the photosensitive resin composition of the present disclosure may contain a polymerizable functional group-containing monomer (D). The polymerizable functional group-containing monomer (D) is preferably a radical polymerizable compound that undergoes a radical polymerization reaction with the photopolymerization initiator (C), for example, a (meth)acrylic compound.

The polymerizable functional group-containing monomer (D) preferably contains at least one selected from the group consisting of a monofunctional monomer (D1) containing one polymerizable functional group in the molecule and a polyfunctional monomer (D2) containing two or more polymerizable functional groups in the molecule, and the polymerizable functional group-containing monomer (D) more preferably contains both (D1) and (D2).

Examples of the monofunctional monomer (D1) include, but not particularly limited to, 2-hydroxyethyl (meth)acrylate, 2-hydroxypropyl methacrylate, 2-hydroxybutyl methacrylate, 4-hydroxybutyl acrylate, 2-hydroxy-3-phenoxypropyl acrylate, methoxypolyethylene glycol monomethacrylate, 2-ethylhexyl (meth)acrylate, butoxydiethylene glycol methacrylate, isobornyl (meth)acrylate, m-phenoxybenzyl acrylate, o-phenylphenoxyethyl acrylate, 4-methacryloyloxybenzophenone, EO-modified p-cumylphenol acrylate, nonylphenoxyethyl acrylate, 6-acrylamidohexanoic acid, tris-(2-acryloxyethyl)isocyanurate, tris-(2-hydroxyethyl)isocyanurate acrylate, 2-[[2-(methacryloyloxy)ethoxy]carbonyl]benzoic acid, methacryloyloxyethyl succinic acid, and 2-acryloyloxyethyl succinic acid.

Examples of the polyfunctional monomer (D2) include: pentaerythritol tetraacrylate; di(meth)acrylates of ethylene glycol or polyethylene glycol, such as diethylene glycol dimethacrylate and tetraethylene glycol dimethacrylate; di(meth)acrylates of propylene glycol or polypropylene glycol; di(meth)acrylates and tri(meth)acrylates of glycerol; cyclohexane di(meth)acrylate; 1,4-butanediol di(meth)acrylate; 1,6-hexanediol di(meth)acrylate; neopentyl glycol di(meth)acrylate; di(meth)acrylates and (meth)acrylamides of bisphenol A, and derivatives thereof; trimethylolpropane tri(meth)acrylate; di(meth)acrylates and tri(meth)acrylates of glycerol; di(meth)acrylates, tri(meth)acrylates, and tetra(meth)acrylates of pentaerythritol; ethylene oxide or propylene oxide adducts of these compounds; and urethane acrylates, such as KRM 7735 (product name, manufactured by DAICEL-ALLNEX Ltd.), EBECRYL 230 (product name, manufactured by DAICEL-ALLNEX Ltd.), EBECRYL 4491 (product name, manufactured by DAICEL-ALLNEX Ltd.), EBECRYL 8413 (product name, manufactured by DAICEL-ALLNEX Ltd.), EBECRYL 8411 (product name, manufactured by DAICEL-ALLNEX Ltd.), EBECRYL 8402 (product name, manufactured by DAICEL-ALLNEX Ltd.), EBECRYL 8465 (product name, manufactured by DAICEL-ALLNEX Ltd.), EBECRYL 8667 (product name, manufactured by DAICEL-ALLNEX Ltd.), EBECRYL 4740 (product name, manufactured by DAICEL-ALLNEX Ltd.), and KRM 9276 (product name, manufactured by DAICEL-ALLNEX Ltd.). Among these radical polymerizable compounds, from the standpoint of inhibiting the cure shrinkage, the polymerizable functional group-containing monomer (D) preferably contains a compound having three or more radical polymerizable functional groups.

In these monomers, the weight ratio of the monofunctional monomer (D1) and the polyfunctional monomer (D2) preferably satisfies the following: 0.01<D1/D2≤1. From the standpoint of the flatness during coating, the ratio D1/D2 is preferably higher than 0.01, more preferably higher than 0.1 and, from the standpoint of the post-curing flatness, the ratio D1/D2 is preferably 1 or lower, more preferably lower than 0.5.

The content of the polymerizable functional group-containing monomer (D) in the photosensitive resin composition of the present disclosure is preferably 0.5 parts by mass to 100 parts by mass with respect to 100 parts by mass of the polyimide (A). From the standpoint of the photocurability, a lower limit value of the content is more preferably 5 parts by mass or more, still more preferably 10 parts by mass or more. From the standpoint of the copper adhesion and the bottom curing of a pattern, an upper limit value of the content is more preferably 50 parts by mass or less, still more preferably 40 parts by mass or less.

### (E) Silane Coupling Agent

For the purpose of improving the adhesion of a cured relief pattern, the photosensitive resin composition of the present disclosure may optionally contain a silane coupling agent (E). The silane coupling agent (E) preferably has a structure represented by the following Formula (38).

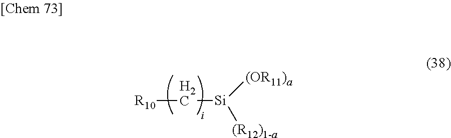

(wherein, R₁₀ represents at least one selected from the group consisting of substituents containing an epoxy group, a phenylamino group, a ureido group, an isocyanate group, and an isocyanurate group; R₁₁ each independently represents an alkyl group having 1 to 4 carbon atoms; R₁₂ represents a hydroxyl group and an alkyl group having 1 to 4 carbon atoms; a represents an integer of 1 to 3; and i represents an integer of 1 to 6)

In Formula (38), a is not limited as long as it is an integer of 1 to 3; however, from the standpoint of, for example, the adhesion with a metal rewiring layer, a is preferably 2 or 3, more preferably 3. Further, i is not limited as long as it is an integer of 1 to 6; however, from the standpoint of the adhesion with a metal rewiring layer, i is preferably 1 to 4. From the standpoint of the resolution, i is preferably 2 to 5.

R₁₀ is not limited as long as it is a substituent containing any structure of the group consisting of an epoxy group, a phenylamino group, a ureido group, an isocyanate group, and an isocyanurate group. Particularly, from the standpoint of the resolution and the adhesion with a metal rewiring layer, R₁₀ is preferably at least one selected from the group consisting of substituents containing a phenylamino group and a ureido group, more preferably a substituent containing a phenylamino group.

R₁₁ is not limited as long as it is an alkyl group having 1 to 4 carbon atoms. Examples thereof include a methyl group, an ethyl group, a propyl group, an isopropyl group, a butyl group, an isobutyl group, and a t-butyl group.

R₁₂ is not limited as long as it is a hydroxyl group and an alkyl group having 1 to 4 carbon atoms. Examples of this alkyl group having 1 to 4 carbon atoms include the same alkyl groups as those exemplified above for R₁₁.

Examples of an epoxy group-containing silane coupling agent include 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, and 3-glycidoxypropyltriethoxysilane.

Examples of a phenylamino group-containing silane coupling agent include N-phenyl-3-aminopropyltrimethoxysilane.

Examples of a ureido group-containing silane coupling agent include 3-ureidopropyltrialkoxysilane.

Examples of an isocyanate group-containing silane coupling agent include 3-isocyanatopropyltriethoxysilane.

The content of the silane coupling agent (E) in the photosensitive resin composition of the present disclosure is 0.2 parts by mass to 10 parts by mass with respect to 100 parts by mass of the polyimide (A) and, from the standpoint of the copper adhesion, a lower limit value of the content is more preferably 0.5 parts by mass or more, still more preferably 1 part by mass or more. From the standpoint of the generation of foreign materials caused by precipitation, an upper limit value of the content is more preferably 8 parts by mass or less, still more preferably 6 parts by mass or less.

### (F) Organic Titanium Compound

For the purpose of improving the chemical resistance of a cured film, the photosensitive resin composition of the present disclosure may optionally contain an organic titanium compound (F).

Examples of the organic titanium compound of the present disclosure include compounds in which an organic group is bound to a titanium atom via a covalent bond or an ionic bond. Specific examples of the organic titanium compound are enumerated in I) to VII) below:
I) titanium chelate compounds: specific examples include titanium (IV) oxide acetylacetonate, titanium bis(triethanolamine) diisopropoxide, titanium di(n-butoxide)bis(2,4-pentanedionate, titanium diisopropoxide bis(2,4-pentanedionate), titanium diisopropoxide bis(tetramethylheptanedionate), and titanium diisopropoxide bis(ethylacetoacetate).
II) tetraalkoxy titanium compounds: examples include titanium tetra(n-butoxide), titanium tetraethoxide, titanium tetra(2-ethylhexoxide), titanium tetraisobutoxide, titanium tetraisopropoxide, titanium tetramethoxide, titanium tetramniethoxypropoxide, titanium tetramethylphenoxide, titanium tetra(n-nonyloxide), titanium tetra(n-propoxide), titanium tetrastearyloxide, and titanium tetrakis[bis(2,2-(allyloxymethyl)butoxide)].
III) titanocene compounds: examples include pentamethylcyclopentadienyl titanium trimethoxide, bis(η⁵-2,4-cyclopentadien-1-yl)bis(2,6-difluorophenyl)titanium, and bis(η⁵-2,4-cyclopentadien-1-yl)bis(2,6-difluoro-3-(1H-pyrrol-1-yl)phenyl)titanium.
IV) monoalkoxy titanium compounds: examples include titanium tris(dioctylphosphate)isopropoxide and titanium tris(dodecylbenzenesulfonate) isopropoxide.
V) titanium oxide compounds: examples include titanium oxide bis(pentanedionate), titanium oxide bis(tetramniethylheptanedionate), and phthalocyanine titanium oxide.
VI) titanium tetraacetylacetonate compounds: examples include titanium tetraacetylacetonate.
VII) titanate coupling agents: examples include isopropyltridodecylbenzenesulfonyl titanate.

Among the above-described compounds, the organic titanium compound is preferably at least one compound selected from the group consisting of the above-described I) titanium chelate compounds, II) tetraalkoxy titanium compounds, and III) titanocene compounds, from the standpoint of obtaining superior chemical resistance.

Particularly, titanium diisopropoxide bis(ethylacetoacetate), titanium tetra(n-butoxide), bis(η⁵-2,4-cyclopentadien-1-yl)bis(2,6-difluoro-3-(1H-pyrrol-1-yl)phenyl)titanium, and titanium (IV) oxide acetylacetonate are preferred.

When the negative photosensitive resin composition of the present disclosure contains the organic titanium compound (F), the content thereof is preferably 0.05 parts by mass to 10 parts by mass with respect to 100 parts by mass of the polyimide (A). From the standpoint of the heat resistance and the chemical resistance of the resulting cured film, a lower limit value of the content is more preferably 0.5 parts by mass or more. From the standpoint of the storage stability of the negative photosensitive resin composition of the present disclosure, an upper limit value of the content is more preferably 2 parts by mass or less.

### (G) Thermal Crosslinking Agent

For the purpose of inhibiting the cure shrinkage of a cured film, the negative photosensitive resin composition of the present disclosure may optionally contain a thermal crosslinking agent.

The “thermal crosslinking agent (G)” means a compound that causes an addition reaction or a condensation polymerization reaction with heat. These reactions occur between the polyimide (A) and the thermal crosslinking agent (G), between the thermal crosslinking agents (G), and between the thermal crosslinking agent (G) and the below-described other components, and the reaction temperature is preferably 150° C. or higher.

Examples of the thermal crosslinking agent (G) include alkoxymethyl compounds, epoxy compounds, oxetane compounds, bismaleimide compounds, allyl compounds, and blocked isocyanate compounds. From the standpoint of inhibiting the cure shrinkage, the thermal crosslinking agent (G) preferably contains a nitrogen atom.

Examples of the alkoxymethyl compounds include, but not limited to, the following compounds.

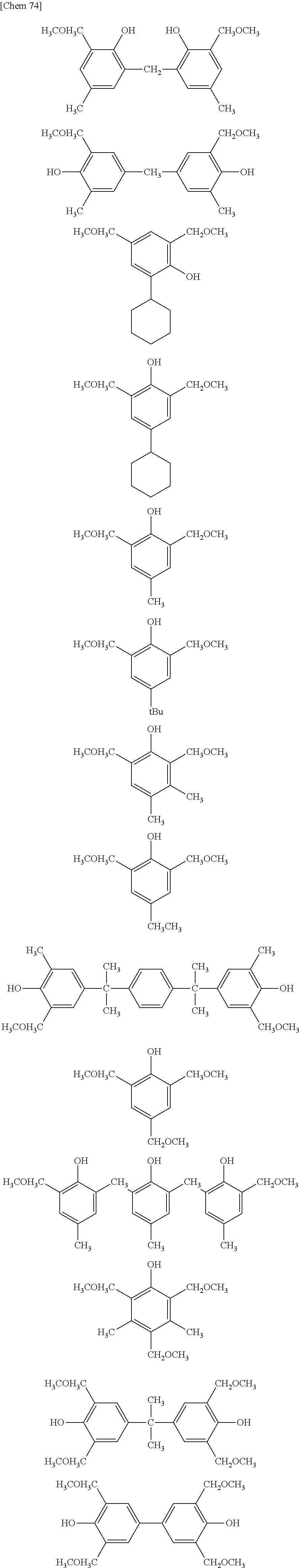

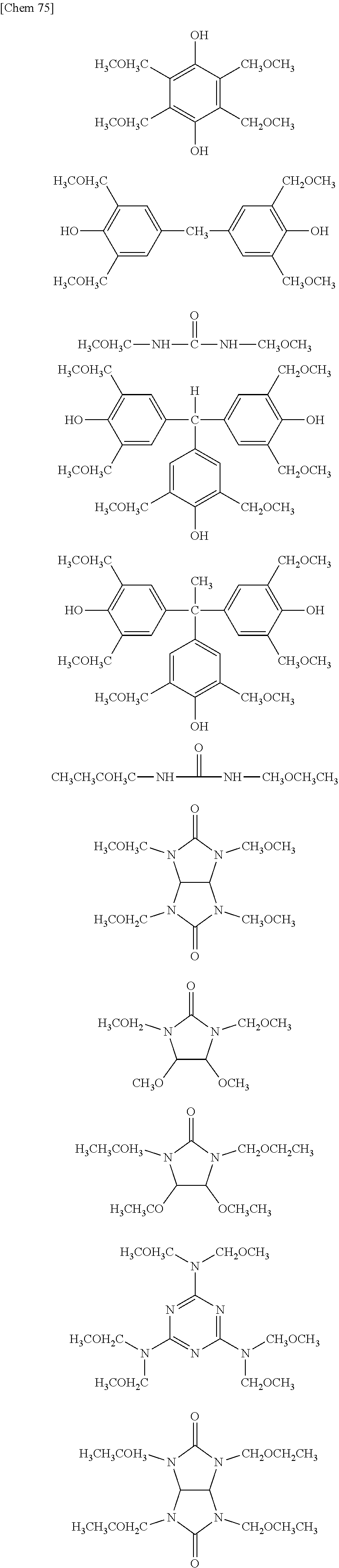

Examples of the epoxy compounds include 4-hydroxybutyl acrylate glycidyl ether, epoxy compounds containing a bisphenol A-type group, and hydrogenated bisphenol A diglycidyl ether (e.g., EPOLITE 4000 manufactured by Kyoeisha Chemical Co., Ltd.).

Examples of the oxetane compounds include 1,4-bis{[(3-ethyl-3-oxetanyl)methoxy]methyl}benzene, bis[l-ethyl(3-oxetanyl)]methyl ether, 4,4′-bis[(3-ethyl-3-oxetanyl)methyl]biphenyl, 4,4′-bis(3-ethyl-3-oxetanylmethoxy)biphenyl, ethylene glycol bis(3-ethyl-3-oxetanylmethyl) ether, diethylene glycol bis(3-ethyl)-3-oxetanylmethyl) ether, bis(3-ethyl-3-oxetanylmethyl) diphenoate, trimethylolpropane tris(3-ethyl-3-oxetanylmethyl) ether, pentaerythritol tetrakis(3-ethyl-3-oxetanylmethyl) ether, poly[[3-[(3-ethyl-3-oxetanyl)methoxy]propyl]silsesquioxane]derivatives, oxetanyl silicate, phenol novolac-type oxetane, 1,3-bis[(3-ethyloxetan-3-yl)methoxy]benzene, OXT121 (trade name, manufactured by Toagosei Co., Ltd.), OXT221 (trade name, manufactured by Toagosei Co., Ltd.).

Examples of the bismaleimide compounds include 1,2-bis(maleimide)ethane, 1,3-bis(maleimide)propane, 1,4-bis(maleimide)butane, 1,5-bis(maleimide)pentane, 1,6-bis(maleimide)hexane, 2,2,4-trimethyl-1,6-bis(maleimide)hexane, N,N-1,3-phenylenebis(maleimide), 4-methyl-N,N-1,3-phenylenebis(maleimide), N,N-1,4-phenylenebis(maleimide), 3-methyl-N,N-1,4-phenylenebis(maleimide), 4,4′-bis(maleimide)diphenylmethane, 3,3′-diethyl-5,5′-dimethyl-4,4′-bis(maleimide)diphenylmethane, and 2,2-bis[4-(4-maleimidophenoxy)phenyl]propane.

Examples of the allyl compounds include allyl alcohol, allylanisole, benzoic acid allyl ester, cinnamic acid allyl ester, N-allyloxyphthalimide, allyl phenol, allyl phenyl sulfone, allyl urea, diallyl phthalate, diallyl isophthalate, diallyl terephthalate, diallyl maleate, diallyl isocyanurate, triallylamine, triallyl isocyanurate, triallyl cyanurate, triallylamine, triallyl 1,3,5-benzenetricarboxylate, triallyl trimellitate, triallyl phosphate, triallyl phosphite, and triallyl citrate.

Examples of the blocked isocyanate compounds include hexamethylene diisocyanate-based blocked isocyanates (e.g., DURANATE SBN-70D, SBB-70P, SBF-70E, TPA-B80E, 17B-60P, MF-B60B, E402-B80B, MF-K60B, and WM44-L70G, which are manufactured by Asahi Kasei Co., Ltd.; TAKENATE B-882N manufactured by Mitsui Chemicals, Inc.; and 7960, 7961, 7982, 7991, and 7992, which are manufactured by Baxenden Chemicals Limited), tolylene diisocyanate-based blocked isocyanates (e.g., TAKENATE B-830 manufactured by Mitsui Chemicals, Inc.), 4,4′-diphenylmethane diisocyanate-based blocked isocyanates (e.g., TAKENATE B-815N manufactured by Mitsui Chemicals, Inc.; and BLONATE PMD-OA01 and PMD-MA01, which are manufactured by Daiei Sangyo Kaisha, Ltd.), 1,3-bis(isocyanatomethyl)cyclohexane-based blocked isocyanates (e.g., TAKENATE B-846N manufactured by Mitsui Chemicals, Inc.; and CORONATE BI-301, 2507, and 2554, which are manufactured by Tosoh Corporation), and isophorone diisocyanate-based blocked isocyanates (e.g., 7950, 7951, and 7990, which are manufactured by Baxenden Chemicals Limited).

Among these compounds, blocked isocyanate compounds and bismaleimide compounds are preferred from the standpoint of the storage stability.

The thermal crosslinking agent (G) may be used singly, or in combination of two or more kinds thereof.

The content of the thermal crosslinking agent (G) in the negative photosensitive resin composition of the present disclosure is preferably 0.2 parts by mass to 40 parts by mass with respect to 100 parts by mass of the polyimide (A). From the standpoint of the chemical resistance, a lower limit value of the content is more preferably 1 part by mass or more, still more preferably 10 parts by mass or more. From the standpoint of the storage stability of the negative photosensitive resin composition, an upper limit value of the content is more preferably 30 parts by mass or less, still more preferably 20 parts by mass or less.

### (H) Rust Inhibitor

When the negative photosensitive resin composition of the present disclosure is used to form a cured film on a substrate made of copper or a copper alloy, in order to inhibit the discoloration on copper, the negative photosensitive resin composition of the present disclosure may optionally contain a rust inhibitor.

Examples of the rust inhibitor include azole compounds and purine compounds.

Examples of the azole compounds include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 3-mercapto-1,2,4-triazole, 1H-tetrazole, 5-methyl-1H-tetrazole, 5-phenyl-1H-tetrazole, 5-amino-1H-tetrazole, and 1-methyl-1H-tetrazole.

Examples of particularly preferred azole compounds include 5-amino-1H-tetrazole, tolyltriazole, 5-methyl-1H-benzotriazole, and 4-methyl-1H-benzotriazole. These azole compounds may be used singly, or as a mixture of two or more thereof.

Specific examples of the purine compounds include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, 9-(2-hydroxyethyl)adenine, guanine oxime, N-(2-hydroxyethyl)adenine, 8-aminoadenine, 6-amino-8-phenyl-9H-purine, 1-ethyladenine, 6-ethylaminopurine, 1-benzyladenine, N-methylguanine, 7-(2-hydroxyethyl)guanine, N-(3-chlorophenyl)guanine, N-(3-ethylphenyl)guanine, 2-azaadenine, 5-azaadenine, 8-azaadenine, 8-azaguanine, 8-azapurine, 8-azaxanthine, 8-azahypoxanthine, and derivatives thereof.

When the negative photosensitive resin composition of the present disclosure contains the rust inhibitor (H), the content thereof is preferably 0.01 parts by mass to 20 parts by mass with respect to 100 parts by mass of the polyimide (A). When the negative photosensitive resin composition of the present disclosure is formed on copper or a copper alloy, discoloration of the surface of copper or the copper alloy is inhibited; therefore, a lower limit value of the content of the rust inhibitor (H) is more preferably 0.03 parts by mass or more, still more preferably 0.05 parts by mass or more. From the standpoint of the photosensitivity, the lower limit value of the content of the rust inhibitor (H) is more preferably 10 parts by mass or less, still more preferably 5 parts by mass or less.

### (I) Thermal Polymerization Initiator

The negative photosensitive resin composition of the present disclosure may also contain a thermal polymerization initiator. This thermal polymerization initiator refers to a compound that generates radicals with heat, and examples thereof include: organic peroxides, such as dialkyl peroxides, diacyl peroxides, peroxy esters, and peroxy ketals; and azo-based polymerization initiators, such as azonitriles, azo esters, and azo amides. Thereamong, dialkyl peroxides and diacyl peroxides (e.g., dicumyl peroxide) are preferred from the standpoint of the chemical resistance.

When the negative photosensitive resin composition of the present disclosure contains the thermal polymerization initiator (I), the content thereof is preferably 0.1 parts by mass to 10 parts by mass with respect to 100 parts by mass of the polyimide (A). From the standpoint of the chemical resistance, a lower limit value of the content is more preferably 0.5 parts by mass or more. From the standpoint of the storage stability of the negative photosensitive resin composition, the lower limit value of the content is more preferably 5 parts by mass or less.

### (J) Plasticizer

The negative photosensitive resin composition of the present disclosure may also contain a plasticizer.

Examples of the plasticizer include: phthalic acid ester compounds typified by bis(2-ethylhexyl) phthalate, dicyclohexyl phthalate, and diphenyl phthalate; isophthalic acid ester compounds typified by bis(2-ethylhexyl) isophthalate, dicyclohexyl isophthalate, and diphenyl isophthalate; terephthalic acid ester compounds typified by bis(2-ethylhexyl) terephthalate, dicyclohexyl terephthalate, and diphenyl terephthalate; trimellitic acid ester compounds typified by tris(2-ethylhexyl) trimellitate, tricyclohexyl trimellitate, and triphenyl trimellitate; pyromellitic acid compounds typified by tetrakis(2-ethylhexyl) pyromellitate, tetracyclohexyl pyromellitate, and tetraphenyl pyromellitate; malonic acid ester compounds typified by bis(2-ethylhexyl) malonate, dicyclohexyl malonate, and diphenyl malonate; succinic acid ester compounds typified by bis(2-ethylhexyl) succinate, dicyclohexyl succinate, and diphenyl succinate; glutaric acid ester compounds typified by bis(2-ethylhexyl) glutarate, dicyclohexyl glutarate, and diphenyl glutarate; adipic acid ester compounds typified by bis(2-ethylhexyl) adipate, dicyclohexyl adipate, and diphenyl adipate; pimelic acid ester compounds typified by bis(2-ethylhexyl) pimelate, dicyclohexyl pimelate, and diphenyl pimelate; suberic acid ester compounds typified by bis(2-ethylhexyl) suberate, dicyclohexyl suberate, and diphenyl suberate; azelaic acid ester compounds typified by bis(2-ethylhexyl) azelate, dicyclohexyl azelate, and diphenyl azelate; sebacic acid ester compounds typified by bis(2-ethylhexyl) sebacate, dicyclohexyl sebacate, and diphenyl sebacate; aliphatic acid tetrahydrofurfuryl compounds typified by tetrahydrofurfiryl propionate, tetrahydrofurfiryl butyrate, and tetrahydrofurfuryl isobutyrate; acrylic polymers typified by DISPARLON 230 (product name, manufactured by Kusumoto Chemicals, Ltd.) and DISPARLON L-1983N (product name, manufactured by Kusumoto Chemicals, Ltd.); silicone compounds typified by DISPARLON 1711EF (product name, manufactured by Kusumoto Chemicals, Ltd.); and fluorine compounds typified by DISPARLON U-158 (product name, manufactured by Kusumoto Chemicals, Ltd.) and DISPARLON U-160 (product name, manufactured by Kusumoto Chemicals, Ltd.).

Thereamong, from the standpoint of the compatibility with the polyimide (A), phthalic acid ester compounds, isophthalic acid ester compounds, terephthalic acid ester compounds, pyromellitic acid ester compounds, trimellitic acid ester compounds, malonic acid ester compounds, succinic acid ester compounds, glutaric acid ester compounds, adipic acid ester compounds, pimelic acid ester compounds, suberic acid ester compounds, azelaic acid ester compounds, sebacic acid ester compounds, and aliphatic acid tetrahydrofurfuryl compounds are preferred.

When the negative photosensitive resin composition of the present disclosure contains the plasticizer (J), the content thereof is preferably 0.5 parts by mass to 40 parts by mass with respect to 100 parts by mass of the polyimide (A). From the standpoint of the flatness during coating, a lower limit value of the content is more preferably 1 part by mass or more. From the standpoint of the post-curing flatness, an upper limit value of the content is more preferably 30 parts by mass or less.

The negative photosensitive resin composition of the present disclosure may further contain components other than the above-described components (A) to (J). Examples of the components other than the components (A) to (J) include, but not limited to, hindered phenol compounds, adhesive aids, sensitizers, thermal polymerization inhibitors, and thermal base generators.

For the purpose of inhibiting the discoloration on the copper surface, the negative photosensitive resin composition of the present disclosure may optionally contain a hindered phenol compound.

Examples of the hindered phenol compound include, but not limited to, 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N-hexamethylene-bis(3,5-di-t-butyl-4-hydroxy-hydrocinnamide), 2,2′-methylene-bis(4-methyl-6-t-butylphenol), 2,2′-methylene-bis(4-ethyl-6-t-butylphenol), pentaerythrityl-tetrakis[3-(3,5-di-t-butyl-4-hydroxyphenyl)propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, and 1,3,5-tris(4-t-butyl-5-ethyl-3-hydroxy-2-methylbenzyl)-1,3,5-triazine-2,4,6-(1H,3H,5H)-trione.

Thereamong, for example, 1,3,5-tris(4-t-butyl-3-hydroxy-2,6-dimethylbenzyl)-1,3,5-triazine-2,4,6-(1H,3H,5H)-trione is particularly preferred.

When the negative photosensitive resin composition of the present disclosure contains a hindered phenol compound, the content thereof is preferably 0.1 parts by mass to 20 parts by mass with respect to 100 parts by mass of the polyimide (A). When the negative photosensitive resin composition is formed on copper or a copper alloy, discoloration and corrosion of copper or the copper alloy are inhibited; therefore, a lower limit value of the content of the hindered phenol compound is more preferably 0.5 parts by mass or more. From the standpoint of the photosensitivity, an upper limit value of the content of the hindered phenol compound is more preferably 10 parts by mass or less.

For the purpose of improving the adhesion between a film formed using the negative photosensitive resin composition and a substrate, the negative photosensitive resin composition of the present disclosure may optionally contain other adhesive aid in addition to the silane coupling agent. As the other adhesive aid, for example, an aluminum-based adhesive aid can be used.

Examples of the aluminum-based adhesive aid include aluminum tris(ethylacetoacetate), aluminum tris(acetylacetonate), and ethylacetoacetate aluminum diisopropylate.

When the negative photosensitive resin composition of the present disclosure contains an adhesive aid, the content thereof is preferably 0.01 parts by mass to 25 parts by mass with respect to 100 parts by mass of the polyimide (A). From the standpoint of the adhesion, a lower limit value of the content is more preferably 0.5 parts by mass or more. From the standpoint of the storage stability of the negative photosensitive resin composition, an upper limit value of the content is more preferably 20 parts by mass or less.

For the purpose of improving the photosensitivity, the negative photosensitive resin composition of the present disclosure may optionally contain a sensitizer.

Examples of the sensitizer include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobeizal)-4-methylcyclohexanone, 4,4′-bis(dimethylamino)chalcone, 4,4′-bis(diethylamino)chalcone, p-dimethylaminocinnamilideneindanone, p-dimethylaminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobeizal)acetone, 1,3-bis(4′-diethylaminobeizal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobeizothiazole, 2-(p-dimethylaminostyryl)beizoxazole, 2-(p-dimethylaminostyryl)beizthiazole, 2-(p-dimethylaminostyryl)naphtho(1,2-d)thiazole, and 2-(p-dimethylaminobenzoyl)styrene. These sensitizers may be used singly, or in combination of plural kinds thereof, for example, two to five kinds thereof.

When the negative photosensitive resin composition of the present disclosure contains a sensitizer for improving the photosensitivity, the content thereof is preferably 0.1 parts by mass to 25 parts by mass with respect to 100 parts by mass of the polyimide (A).

For the purpose of improving the stability of viscosity and photosensitivity during storage particularly in the state of a solution containing the solvent (B), the negative photosensitive resin composition of the present disclosure may optionally contain a thermal polymerization inhibitor.

As the thermal polymerization inhibitor, for example, hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt, or N-nitroso-N-(1-naphthyl)hydroxylamine ammonium salt can be used.

The negative photosensitive resin composition of the present disclosure contains the polyimide (A) represented by Formula (1), the solvent (B), and the photopolymerization initiator (C).

In one mode, the negative photosensitive resin composition of the present disclosure preferably satisfies the following Equation (I):

$$[ Math 2 ]$$

$$80 < \frac{Im}{Fc \times ( Mw / Mn )} \qquad ( I )$$

(wherein, Im represents an imidization rate; Fc represents a post-curing flatness; and Mw/Mn represents a molecular weight distribution of the polyimide (A)).

Fc is a value relating to the post-curing flatness and, specifically, in cross-sectional SEM observation of a cured film, Fc means the unevenness of the cured film surface in a region having a side length of 10 μm.

More specifically, Fc is evaluated by the method described below in the section of Examples. The term “unevenness of the cured film surface” used herein refers to a difference between a maximum height of protruding parts of the cured film surface and a minimum height of recessed parts of the cured film surface.

Fc is preferably less than 0.65 μm, more preferably 0.50 μm or more but less than 0.65 μm, still more preferably 0.35 μm or more but less than 0.50 μm, particularly preferably less than 0.35 μm.

The protruding parts of the cured film surface correspond to a total thickness of a cured relief pattern and the cured film. The recessed parts of the cured film surface correspond to the thickness of the cured film formed on a via of the cured relief pattern.

The negative photosensitive resin composition of the present disclosure that satisfies the above-described Equation (I) is excellent in flatness during coating, post-curing flatness, copper adhesion, and resolution.

The value of the right-hand side of Equation (I) is preferably larger than 80, more preferably larger than 130, still more preferably larger than 180, particularly preferably larger than 230.

An upper limit value of the right-hand side of Equation (1) is 15,000.

### <Method of Producing Cured Relief Pattern>

The method of producing a cured relief pattern according to the present disclosure includes:
(1) the step of applying the above-described negative photosensitive resin composition of the present disclosure onto a substrate to form a photosensitive resin layer on the substrate (resin layer forming step);
(2) the step of exposing the photosensitive resin layer (exposure step);
(3) the step of developing the thus exposed photosensitive resin layer to form a relief pattern (relief pattern forming step); and
(4) the step of heat-treating the relief pattern to form a cured relief pattern (cured relief pattern forming step).

### (1) Resin Layer Forming Step

In this step, the negative photosensitive resin composition of the present disclosure is applied onto a substrate and subsequently dried if necessary to form a photosensitive resin layer.

As an application method, any method that is conventionally employed for applying a negative photosensitive resin composition, for example, a method of applying the negative photosensitive resin composition using a spin coater, a bar coater, a blade coater, a curtain coater, a screen printer or the like, or a spray-coating method using a spray coater, may be employed.

If necessary, the resulting coating film containing the negative photosensitive resin composition may be dried.

As a drying method, for example, air drying, heat drying using an oven or a hot plate, or vacuum drying may be employed. Specifically, in the case of air drying or heat drying, the drying can be performed at 20° C. to 150° C. for 1 minute to 1 hour. In the above-described manner, a photosensitive resin layer can be formed on the substrate.

### (2) Exposure Step

In this step, the photosensitive resin layer formed above is exposed with a UV light source or the like either directly or through a patterned photomask or reticle using an exposure device, such as a contact aligner, a mirror projector, or a stepper. By this exposure, the photopolymerizable functional group of the polyimide (A) contained in the negative photosensitive resin composition is crosslinked by the action of the photopolymerization initiator (C). This crosslinking makes the exposed portion insoluble in the below-described developing liquid; therefore, a relief pattern can be formed.

Subsequently, for the purpose of, for example, improving the photosensitivity, if necessary, either or both of post-exposure baking (PEB) and pre-development baking may be performed using an arbitrary combination of temperature and time. As for the baking conditions, the temperature is preferably 40° C. to 120° C. and the time is preferably 10 seconds to 240 seconds; however, the baking conditions are not limited to these ranges as long as various properties of the negative photosensitive resin composition of the present disclosure are not impaired.

### (3) Relief Pattern Forming Step

In this step, the unexposed portion of the exposed photosensitive resin layer is developed and removed to form a relief pattern. As a method of developing the exposed (irradiated) photosensitive resin layer, any method can be selected from conventionally known photoresist developing methods, such as a rotary spray method, a puddle method, and an immersion method accompanied by ultrasonication. After the development, for the purpose of, for example, adjusting the shape of the relief pattern, if necessary, post-development baking may be performed using an arbitrary combination of temperature and time.

The developing liquid used for the development is preferably, for example, a good solvent for the negative photosensitive resin composition, or a combination of a good solvent and a poor solvent.

The good solvent is preferably, for example, N-methyl-2-pyrrolidone, N-cyclohexyl-2-pyrrolidone, N,N-dimethylacetamide, cyclopentanone, cyclohexanone, γ-butyrolactone, or α-acetyl-γ-butyrolactone.

The poor solvent is preferably, for example, toluene, xylene, methanol, ethanol, isopropyl alcohol, ethyl lactate, propylene glycol methyl ether acetate, or water. When a good solvent and a poor solvent are used as a mixture, it is preferred to adjust the ratio of the poor solvent with respect to the good solvent in accordance with the solubility of the polymer contained in the negative photosensitive resin composition. These solvents may be used in combination of two or more kinds thereof, for example, several kinds thereof.

### (4) Cured Relief Pattern Forming Step

In this step, the relief pattern obtained by the development is heat-treated to vaporize the photosensitive component and thereby form a cured relief pattern composed of the polyimide. A heat treatment method can be selected from various methods, such as a method using a hot plate, a method using an oven, and a method using a temperature-programmable heating oven. The heat treatment can be performed, for example, at 160° C. to 350° C. for 30 minutes to 5 hours. The temperature of the heat treatment is preferably 300° C. or lower, more preferably 250° C. or lower.

As an atmosphere gas during heat-curing, air may be used, and an inert gas such as nitrogen or argon can be used as well.

It is noted here that the exposed photosensitive resin layer has a crosslinked structure formed by crosslinking of the photopolymerizable functional group of the polyimide (A).

### <Polyimide Cured Film>

The present disclosure also provides a polyimide cured film obtained by curing the negative photosensitive resin composition of the present disclosure. The cured film formed from the negative photosensitive resin composition of the present disclosure contains a polyimide having a structure represented by the following Formula (1). Further, the cured film of the present disclosure contains a cured product of the negative photosensitive resin composition of the present disclosure.

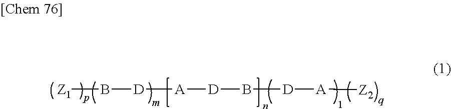

{wherein, A represents a tetracarboxylic dianhydride-derived structure; B represents a diamine-derived structure; D represents an imide structure; Z₁ and Z₂ each represent a monovalent organic group that contains a photopolymerizable functional group and at least one linking group selected from the group consisting of an ester bond, a urea bond, and an amide bond, which photopolymerizable functional group exists on an end of Z₁ and/or that of Z₂, and which Z₁ and Z₂ are optionally the same or different; 1 and m each represent an integer of 0 or 1, satisfying l+m=1; n represents an integer of 1 to 30; and p and q each represent an integer of 0 to 2,satisfying p+q≥1}

In the cured film, Z₁ and Z₂ are each crosslinked in the above-described exposure step of the cured relief pattern formation.

### <Semiconductor Device>

The present disclosure also provides a semiconductor device including a cured relief pattern obtained from the above-described negative photosensitive resin composition. Specifically, the present disclosure provides a semiconductor device which includes a substrate that is a semiconductor element, and a cured relief pattern. The cured relief pattern may be produced by the above-described method of producing a cured relief pattern using the above-described negative photosensitive resin composition.

The present disclosure also provides a method of producing a semiconductor device, which method uses a semiconductor element as a substrate and includes the above-described method of producing a cured relief pattern according to the present embodiment as a part of a step. In this case, a semiconductor device can be produced by forming a cured relief pattern by the method of producing a cured relief pattern according to the present disclosure as, for example, a surface protective film of a semiconductor device, an interlayer insulating film, a rewiring insulating film, a protective film for a flip-chip device, or a protective film of a semiconductor device having a bump structure, and combining the cured relief pattern with a known method of producing a semiconductor device.

### <Display Device>

The present disclosure also provides a display device including a display element and a cured film arranged on top of the display element, in which the cured film is the above-described cured relief pattern. The cured relief pattern may be laminated in direct contact with the display element, or other layer may be interposed therebetween. The cured film can be applied to, for example, surface protective films, insulating films, planarization films, and the like of TFT liquid crystal display elements and color filter elements; protrusions for MVA-type liquid crystal display devices; and partition walls for organic EL element cathodes.

The negative photosensitive resin composition of the present disclosure is also useful for applications such as interlayer insulation of multilayer circuits, cover coating of flexible copper-dad plates, solder resist films, and liquid crystal alignment films, in addition to the above-described application to a semiconductor device.

### <Method of Producing Negative Photosensitive Resin Composition>

The method of producing a negative photosensitive resin composition according to the present disclosure includes: the step of producing a polyimide (A) by the method described above in “Method of Producing Polyimide (A)”; and the step of mixing 100 parts by mass of the polyimide (A) with 30 to 1,000 parts by mass of a solvent (B) and 1 to 30 parts by mass of a photopolymerization initiator (C) to obtain the negative photosensitive resin composition of the present disclosure.

Optionally and selectively, additives selected from the above-described polymerizable functional group-containing monomer (D), silane coupling agent (E), organic titanium compound (F), thermal crosslinking agent (G), rust inhibitor (H), thermal polymerization initiator (I), and plasticizer (J), as well as other components may be further incorporated.

### EXAMPLES

The present embodiment will now be described concretely by way of Examples; however, the present embodiment is not limited thereto. In Examples, Comparative Examples, Production Examples, and Synthesis Examples, the physical properties of a polyimide, a polyimide precursor, or a negative photosensitive resin composition (hereinafter, referred to as “resin”) were measured and evaluated in accordance with the below-described respective methods.

### <Methods for Measurement and Evaluation of Physical Properties of Resin>

### (1) Weight-Average Molecular Weight

The weight-average molecular weight (Mw) and the number-average molecular weight (Mn) of each resin were measured by gel permeation chromatography (in terms of standard polystyrene) under the below-described conditions. Further, the molecular weight distribution of the polymer was calculated as Mw/Mn.

As a solvent, N,N-dimethylformamide (manufactured by FUJIFILM Wako Pure Chemical Corporation, for high-performance liquid chromatography; 24.8 mmol/L of lithium bromide monohydrate (manufactured by FUJIFILM Wako Pure Chemical Corporation, purity: 99.5%) and 63.2 mmol/L of phosphoric acid (manufactured by FUJIFILM Wako Pure Chemical Corporation, for high-performance liquid chromatography) were added and dissolved immediately before the measurement) was used. A calibration curve for the calculation of the weight-average molecular weight was prepared using a standard polystyrene (EASICAL Type PS-1, manufactured by Agilent Technologies, Inc.).
Apparatus: HLC-8220GPC (manufactured by Tosoh Corporation)
Columns: 2×TSK GEL SUPER HM-H (manufactured by Tosoh Corporation)
Flow rate: 0.5 mL/min
Column temperature: 40° C.
Detector: UV-8220 (UV-VIS: UV-visible spectrometer, manufactured by Tosoh Corporation)

### (2) Imidization Rate (Im)

The imidization rate (Im) of each resin was calculated by the following equation using an integral value d of amide group-derived proton around 10.5 ppm that was measured by a nuclear magnetic resonance method (NMR, nuclide: 1H) and a theoretical integral ratio α of amide group-derived proton of polyamic acid before dehydration and ring closure. The values of α′ and α were normalized based on the peak around 6.5 to 8.5 ppm attributed to an aromatic structure of the polymer main chain.

$$Im [ \% ] = ( 1 - {α}^{′} / α ) \times 100$$

The NMR measurement was performed under the following conditions.
Apparatus: ECS400 (manufactured by JEOL Ltd.)
Deuterated solvent: dimethyl sulfoxide-d6 (manufactured by FUJIFILM Wako Pure Chemical Corporation)
Measurement temperature: 23° C.

### (3) Production of Cured Relief Pattern for Evaluation of Flatness During Coating

On a 6-inch silicon wafer (manufactured by Fujimi Incorporated, thickness: 625±25 μm), a photosensitive resin composition prepared by the below-described method was spin-coated using a coater developer (model D-Spin 60A, manufactured by SOKUDO Co., Ltd.), and the resultant was prebaked on a hot plate at 110° C. for 180 seconds to form a coating film of about 15 μm in thickness. This coating film was irradiated with an energy of 1,000 mJ/cm² using PRISMA GHI (manufactured by Ultratech, Inc.) with a test-patterned mask.

Subsequently, the coating film was spray-developed with cyclopentanone as a developing liquid using a coater developer (model D-Spin 60A, manufactured by SOKUDO Co., Ltd.) for a period calculated by multiplying the time required for complete dissolution and elimination of unexposed parts by 1.4, after which the coating film was spin-spray rinsed with propylene glycol methyl ether acetate for 10 seconds to obtain a relief pattern on Si.

The wafer having the relief pattern formed on Si was heat-treated in a nitrogen atmosphere at 230° C. for 2 hours using a temperature-programmable curing furnace (model VF-2000, manufactured by Koyo Lindberg Co., Ltd.) to obtain a cured relief pattern that was made of the resin composition at a thickness of about 12 μm on Si and had a via (circular opening) of 10 μm in diameter.

On the thus obtained cured relief pattern, 200 nm thick Ti and 400 nm thick Cu were sputtered in this order using a sputtering device (model L-440S-FHL, manufactured by Cannon Anelva Corporation).

### (4) Evaluation of Flatness During Coating

As evaluation of the in-plane uniformity during coating, the flatness during coating was evaluated as follows.

Onto the relief pattern obtained in (3) above, a photosensitive resin composition prepared by the below-described method was applied by spin coating using a coater developer (model D-Spin 60A, manufactured by SOKUDO Co., Ltd.) such that the post-drying thickness of the resulting film was 7 μm, and the resultant was dried at 110° C. for 180 seconds to form a substrate having a coating film of the photosensitive resin composition.

The thus obtained substrate having the coating film was split along an imaginary line passing through the center of the above-described via, and the resulting cross-section was polished to obtain a cross-sectional SEM observation image. By cross-sectional SEM observation, the surface unevenness of the coating film in the via having a mask opening side of 10 μm was evaluated based on the following criteria.
“Excellent”: less than 0.2 μm
“Good”: 0.2 μm or more but less than 0.35 μm
“Fair”: 0.35 μm or more but less than 0.55 μm
“Poor”: 0.55 μm or more

The value of the surface unevenness is calculated as follows.

That is, the difference between a total thickness of the film of the cured relief pattern obtained by the method of (3) above and the coating film of the photosensitive resin composition formed on the pattern, and the thickness of the coating film of the photosensitive resin composition formed in the via is calculated as the value of the surface unevenness.

### (5) Evaluation of Post-Curing Flatness (Fc)

As an index related to the flatness of a rewiring layer, the post-curing flatness was evaluated as follows. The post-curing flatness is a value derived from a sum of the flatness during coating and the amount of cure shrinkage.

Onto the relief pattern obtained in (3) above, a photosensitive resin composition prepared by the below-described method was applied by spin coating using a coater developer (model D-Spin 60A, manufactured by SOKUDO Co., Ltd.) such that the post-drying thickness of the resulting film was 7 μm, and the resultant was dried at 110° C. for 180 seconds to form a substrate having a coating film of the photosensitive resin composition. The thus obtained coating film was exposed with a high-pressure mercury lamp at 400 mJ/cm².

Subsequently, the substrate was heat-treated in a nitrogen atmosphere at 230° C. for 2 hours using a temperature-programmable curing furnace (model VF-2000, manufactured by Koyo Lindberg Co., Ltd.) to obtain a cured relief pattern (substrate having a cured film).

The thus obtained substrate having the cured film was split along an imaginary line passing through the center of the above-described via, and the resulting cross-section was polished, after which the surface unevenness of the cured film in the via having a mask opening side of 10 μm was determined as Fc by SEM observation of the cross-section. The Fc was evaluated based on the following criteria.
“Excellent”: less than 0.35 μm
“Good”: 0.35 μm or more but less than 0.50 μm
“Fair”: 0.50 μm or more but less than 0.65 μm
“Poor”: 0.65 μm or more

The value of the surface unevenness is calculated as follows.

That is, the difference between a total thickness of the film of the cured relief pattern obtained by the method of (3) above and the cured film of the photosensitive resin composition formed on the pattern, and the thickness of the cured film of the photosensitive resin composition formed in the via is calculated as the value of the surface unevenness.

### (6) Evaluation of Copper Adhesion

On a 6-inch silicon wafer (manufactured by Fujimi Incorporated, thickness: 625±25 μm), 200 nm thick Ti and 400 nm thick Cu were sputtered in this order using a sputtering device (model L-440S-FHL, manufactured by Cannon Anelva Corporation). Then, on this wafer, a photosensitive resin composition prepared by the below-described method was spin-coated using a coater developer (model D-Spin 60A, manufactured by SOKUDO Co., Ltd.), and the resultant was prebaked on a hot plate at 110° C. for 180 seconds to form a coating film on Cu. This coating film was irradiated with an energy of 1,000 mJ/cm² using PRISMA GHI (manufactured by Ultratech, Inc.) without a test-patterned mask.

Subsequently, the wafer was heat-treated in a nitrogen atmosphere at 230° C. for 2 hours using a temperature-programmable curing furnace (model VF-2000, manufactured by Koyo Lindberg Co., Ltd.) to obtain a cured resin coating film made of the resin composition at a thickness of about 6 μm on Cu. For this heat-treated film, in accordance with the cross-cut method prescribed in JIS K5600-5-6, the adhesion properties between the copper substrate and the cured resin coating film were evaluated based on the following criteria.

“Excellent”: The lattice number of the cured resin coating film adhered to the copper substrate was more than 100.

“Good”: The lattice number of the cured resin coating film adhered to the copper substrate was 80 to 100.

“Fair”: The lattice number of the cured resin coating film adhered to the copper substrate was 50 but less than 80.

“Poor”: The lattice number of the cured resin coating film adhered to the copper substrate was less than 50.

### (7) Evaluation of Copper Adhesion After Reliability Test

A cured resin coating film obtained in the same manner as in (6) was placed in a highly accelerated stress test chamber (HASTEST PC-R8D, manufactured by HIRAYAMA Manufacturing Corporation), and treated for 168 hours under the conditions of a temperature of 130° C. and a relative humidity of 85%. After the treatment, the cured film was taken out, and the adhesion between the copper substrate and the cured resin coating film was evaluated in the same manner as in (6) above.

### (8) Evaluation of Chemical Resistance of Cured Relief Pattern (Polyimide Coating Film)

A cured relief pattern formed on Cu in the same manner as in the below-described “(9) Production of Cured Relief Pattern on Cu” was immersed for 5 minutes in a resist stripping solution (product name ST-44, manufactured by ATMI, Inc., main components: 2-(2-aminoethoxy)ethanol and 1-cyclohexyl-2-pyrrolidone) heated to 50° C., washed with running water for 1 minute, and then air-dried. Thereafter, the film surface was visually observed under a light microscope, and the chemical resistance was evaluated based on the presence or absence of damage caused by the chemical solution, such as cracks, and the rate of change in film thickness after chemical treatment.

As for the evaluation criteria, an evaluation of “Excellent” was given when the film had a thickness change rate of 10% or less based on the film thickness prior to the chemical immersion, without the generation of cracks and the like; an evaluation of “Good” was given when the film had a thickness change rate of more than 10% but 15% or less without the generation of cracks and the like; an evaluation of “Fair” was given when the film had a thickness change rate of more than 15% but 20% or less without the generation of cracks and the like; and an evaluation of “Poor” was given when the film had cracks or exhibited a thickness change rate of more than 20%.

### (9) Production of Cured Relief Pattern on Cu

On a 6-inch silicon wafer (manufactured by Fujimi Incorporated, thickness: 625±25 μm), 200 nm thick Ti and 400 nm thick Cu were sputtered in this order using a sputtering device (model L-440S-FHL, manufactured by Cannon Anelva Corporation).

Subsequently, on this wafer, a photosensitive resin composition prepared by the below-described method was spin-coated using a coater developer (model D-Spin 60A, manufactured by SOKUDO Co., Ltd.), and the resultant was prebaked on a hot plate at 110° C. for 180 seconds to form a coating film.

This coating film was irradiated with an energy of 1,000 mJ/cm² using PRISMA GHI (manufactured by Ultratech, Inc.) with a test-patterned mask.

Thereafter, the coating film was spray-developed with cyclopentanone as a developing liquid using a coater developer (model D-Spin 60A, manufactured by SOKUDO Co., Ltd.) for a period calculated by multiplying the time required for complete dissolution and elimination of unexposed parts by 1.4, after which the coating film was spin-spray rinsed with propylene glycol methyl ether acetate for 10 seconds to obtain a relief pattern on Cu.

The wafer having the relief pattern formed on Cu was heat-treated in a nitrogen atmosphere at 230° C. for 2 hours using a temperature-programmable curing furnace (model VF-2000, manufactured by Koyo Lindberg Co., Ltd.) to obtain a cured relief pattern that was made of the photosensitive resin composition at a thickness of about 6 μm on Cu.

### (10) Evaluation of Resolution of Cured Relief Pattern on Cu

The cured relief pattern obtained by the method of (9) above was observed under a light microscope to determine the size of a minimum opening pattern. In this process, if the area of an opening of the obtained pattern was one-half or more of the corresponding pattern mask opening area, the opening was deemed to be resolved, and the length of the mask opening side corresponding to an opening having the smallest area among the resolved openings was defined as the resolution.

An evaluation of “Excellent” was given when the resolution was less than 5 μm; an evaluation of “Good” was given when the resolution was 5 μm or more but less than 7 μm; an evaluation of “Fair” was given when the resolution was 7 μm or more but less than 10 μm; and an evaluation of “Poor” was given when the resolution was 10 μm or more.

### <Production Example 1> (Synthesis of (A) Polyimide A-1)

In a nitrogen-purged three-necked flask to which a Dean-Stark extraction apparatus was attached, 100.0 g of N-methylpyrrolidone (NMP) and 34.9 g (0.1 mol) of 9,9′-bis(4-aminophenyl)fluorene (BAFL) were added and dissolved, and 15.6 g (0.05 mol) of 4,4′-oxydiphthalic dianhydride (ODPA) and 25.0 g of toluene were further added thereto, followed by heating to 180° C.

After confirming that 1.80 g (theoretical amount) of water and 25.0 g of the added toluene were extracted in the Dean-Stark extraction apparatus, heating was stopped, and the resultant was cooled to room temperature.

To the resulting reaction solution, 15.5 g (0.1 mol) of KARENZ MOI (trade name; manufactured by Showa Denko K.K.) was added, and this reaction solution was stirred to obtain a polymer solution. The thus obtained polymer solution was added dropwise to 3 kg of water to precipitate a polymer, which was separated by filtration and then vacuum-dried, whereby a polyimide A-1 having a modified end was obtained in the form of powder.

When the molecular weight of the polyimide A-1 was measured by gel permeation chromatography (in terms of standard polystyrene), the values of Mw, Mn, and Mw/Mn were found to be 4,400, 3,400, and 1.29, respectively.

Further, the alicyclic structure content of the polyimide A-1 was 0% by mole, and the imidization rate of the polyimide A-1 was calculated to be 98% by ¹H-NMR

### <Production Example 2> (Synthesis of (A) Polyimide A-2)

A polyimide A-2 was obtained by performing a reaction in the same manner as in Production Example 1, except that 17.4 g of BAFL and 10.6 g of 2,2′-dimethylbiphenyl-4,4′-diamine (hereinafter “m-tolidine”) were added.

When the molecular weight of the polyimide A-2 was measured by gel permeation chromatography (in terms of standard polystyrene), the values of Mw, Mn, and Mw/Mn were found to be 4,100, 3,200, and 1.28, respectively.

Further, the alicyclic structure content of the polyimide A-2 was 0% by mole, and the imidization rate of the polyimide A-2 was calculated to be 97% by ¹H-NMR

### <Production Example 3> (Synthesis of (A) Polyimide A-3)

A polyimide A-3 was obtained by performing a reaction in the same manner as in Production Example 1, except that BAFL was changed to 27.7 g of 6-(4-aminophenoxy)[1,1′-biphenyl]-3-amine (hereinafter “PDPE”).

When the molecular weight of the polyimide A-3 was measured by gel permeation chromatography (in terms of standard polystyrene), the values of Mw, Mn, and Mw/Mn were found to be 5,500, 4,200, and 1.31, respectively.

Further, the alicyclic structure content of the polyimide A-3 was 0% by mole, and the imidization rate of the polyimide A-3 was calculated to be 99% by ¹H-NMR

### <Production Example 4> (Synthesis of (A) Polyimide A-4)

A polyimide A-4 was obtained by performing a reaction in the same manner as in Production Example 1, except that KARENZ MOI was changed to 23.9 g of KARENZ BEI (trade name; manufactured by Showa Denko K.K.). When the molecular weight of the polyimide A-4 was measured by gel permeation chromatography (in terms of standard polystyrene), the values of Mw, Mn, and Mw/Mn were found to be 5,000, 4,000, and 1.25, respectively.

Further, the alicyclic structure content of the polyimide A-3 was 0% by mole, and the imidization rate of the polyimide A-3 was calculated to be 98% by ¹H-NMR

### <Production Example 5> (Synthesis of (A) Polyimide A-5)

A polyimide A-5 was obtained by performing a reaction in the same manner as in Production Example 1, except that KARENZ MOI was changed to 14.1 g of KARENZ AOI (trade name; manufactured by Showa Denko K.K.). When the molecular weight of the polyimide A-5 was measured by gel permeation chromatography (in terms of standard polystyrene), the values of Mw, Mn, and Mw/Mn were found to be 4,600, 3,900, and 1.18, respectively.

Further, the alicyclic structure content of the polyimide A-5 was 0% by mole, and the imidization rate of the polyimide A-5 was calculated to be 99% by ¹H-NMR

### <Production Example 6> (Synthesis of (A) Polyimide A-6)

A polyimide A-6 was obtained by performing a reaction in the same manner as in Production Example 1, except that KARENZ MOI was changed to 19.9 g of KARENZ MOI-EG (trade name; manufactured by Showa Denko K.K.). When the molecular weight of the polyimide A-6 was measured by gel permeation chromatography (in terms of standard polystyrene), the values of Mw, Mn, and Mw/Mn were found to be 4,600, 3,900, and 1.18, respectively.

Further, the alicyclic structure content of the polyimide A-6 was 0% by mole, and the imidization rate of the polyimide A-6 was calculated to be 100% by ¹H-NMR

### <Production Example 7> (Synthesis of (A) Polyimide A-7)

A polyimide A-7 was obtained by performing a reaction in the same manner as in Production Example 1, except that KARENZ MOI was changed to 10.5 g of methacryloyl chloride (MACI). When the molecular weight of the polyimide A-7 was measured by gel permeation chromatography (in terms of standard polystyrene), the values of Mw, Mn, and Mw/Mn were found to be 4,600, 3,800, and 1.21, respectively.

Further, the alicyclic structure content of the polyimide A-7 was 0% by mole, and the imidization rate of the polyimide A-7 was calculated to be 98% by ¹H-NMR

### <Production Example 8> (Synthesis of (A) Polyimide A-8)

A polyimide A-8 was obtained by performing a reaction in the same manner as in Production Example 1, except that ODPA was changed to 10.9 g of pyromellitic anhydride (hereinafter “PMDA”), BAFL was changed to 16.6 g of PDPE, and the amount of KARENZ MOI was changed to 9.3 g. When the molecular weight of the polyimide A-8 was measured by gel permeation chromatography (in terms of standard polystyrene), the values of Mw, Mn, and Mw/Mn were found to be 18,000, 10,000, and 1.80, respectively.

Further, the alicyclic structure content of the polyimide A-8 was 0% by mole, and the imidization rate of the polyimide A-8 was calculated to be 99% by ¹H-NMR

### <Production Example 9> (Synthesis of (A) Polyimide A-9)

A polyimide A-9 was obtained by performing a reaction in the same manner as in Production Example 1, except that ODPA was changed to 9.8 g of PMDA and 1.0 g of 1,2,3,4-cyclobutanetetracarboxylic anhydride (hereinafter “CBDA”), and BAFL was changed to 16.6 g of PDPE.

When the molecular weight of the polyimide A-9 was measured by gel permeation chromatography (in terms of standard polystyrene), the values of Mw, Mn, and Mw/Mn were found to be 24,000, 13,500, and 1.78, respectively.

Further, the alicyclic structure content of the polyimide A-9 was 5% by mole, and the imidization rate of the polyimide A-9 was calculated to be 98% by ¹H-NMR

### <Production Example 10> (Synthesis of (A) Polyimide A-10)

A polyimide A-10 was obtained by performing a reaction in the same manner as in Production Example 1, except that ODPA was changed to 1.1 g of PMDA and 8.8 g of CBDA, BAFL was changed to 16.6 g of PDPE, and the amount of KARENZ MOI was changed to 9.3 g.

When the molecular weight of the polyimide A-10 was measured by gel permeation chromatography (in terms of standard polystyrene), the values of Mw, Mn, and Mw/Mn were found to be 19,000, 11,000, and 1.73, respectively.

Further, the alicylic structure content of the polyimide A-10 was 41% by mole, and the imidization rate of the polyimide A-10 was calculated to be 99% by 1H-NMR

### <Production Example 11> (Synthesis of (A) Polyimide A-11)

A polyimide A-11 was obtained by performing a reaction in the same manner as in Production Example 1, except that ODPA was changed to 3.8 g of PMDA and 8.1 g of bicyclo[2.2.2]oct-7-ene-2,3,5,6-tetracarboxylic dianhydride (hereinafter “BCD”), BAFL was changed to 16.6 g of PDPE, and the amount of KARENZ MOI was changed to 9.3 g.

When the molecular weight of the polyimide A-11 was measured by gel permeation chromatography (in terms of standard polystyrene), the values of Mw, Mn, and Mw/Mn were found to be 18,000, 10,500, and 1.71, respectively.

Further, the alicylic structure content of the polyimide A-11 was 30% by mole, and the imidization rate of the polyimide A-11 was calculated to be 97% by ¹H-NMR

### <Production Example 12> (Synthesis of (A) Polyimide A-12)

A polyimide A-12 was obtained by performing a reaction in the same manner as in Production Example 1, except that ODPA was changed to 7.1 g of PMDA and 4.3 g of BCD, BAFL was changed to 16.6 g of PDPE, and the amount of KARENZ MOI was changed to 9.3 g.

When the molecular weight of the polyimide A-12 was measured by gel permeation chromatography (in terms of standard polystyrene), the values of Mw, Mn, and Mw/Mn were found to be 17,000, 10,000, and 1.70, respectively.

Further, the alicylic structure content of the polyimide A-12 was 16% by mole, and the imidization rate of the polyimide A-12 was calculated to be 98% by ¹H-NMR

### <Production Example 13> (Synthesis of (A) Polyimide A-13)

A polyimide A-13 was obtained by performing a reaction in the same manner as in Production Example 1, except that ODPA was changed to 12.4 g of BCD, BAFL was changed to 16.6 g of PDPE, and the amount of KARENZ MOI was changed to 9.3 g.

When the molecular weight of the polyimide A-13 was measured by gel permeation chromatography (in terms of standard polystyrene), the values of Mw, Mn, and Mw/Mn were found to be 16,000, 10,000, and 1.60, respectively.

Further, the alicylic structure content of the polyimide A-13 was 46% by mole, and the imidization rate of the polyimide A-13 was calculated to be 100% by ¹H-NMR

### <Production Example 14> (Synthesis of (A) Polyimide A-14)

A polyimide A-14 was obtained by performing a reaction in the same manner as in Production Example 1, except that PDPE in Production Example 10 was changed to 12.0 g of 2-phenoxybenzene-1,4-diamine.

When the molecular weight of the polyimide A-14 was measured by gel permeation chromatography (in terms of standard polystyrene), the values of Mw, Mn, and Mw/Mn were found to be 16,500, 11,000, and 1.50, respectively.

Further, the alicyclic structure content of the polyimide A-14 was 41% by mole, and the imidization rate of the polyimide A-14 was calculated to be 97% by ¹H-NMR

### <Production Example 15> (Synthesis of (A) Polyimide A-15)

In a nitrogen-purged three-necked flask to which a Dean-Stark extraction apparatus was attached, 200 g of γ-butyrolactone (hereinafter “GBL”) and 17.4 g (0.05 mol) of 9,9′-bis(4-aminophenyl)fluorene (BAFL) were added and dissolved, and 31.0 g (0.1 mol) of 4,4′-oxydiphthalic dianhydride (ODPA) and 48.4 g of toluene were further added thereto, followed by heating to 180° C.

After confirming that 1.80 g (theoretical amount) of water and 48.4 g of the added toluene were extracted in the Dean-Stark extraction apparatus, heating was stopped, and the resultant was cooled to room temperature.

Subsequently, to the resulting reaction mixture, a solution obtained by dissolving 45.4 g of dicyclohexylcarbodiimide (DCC) in 45.4 g of GBL was added with stirring under ice-cooling, and this was followed by addition of 28.6 g of 2-hydroxyethyl methacrylate (HEMA). Further, 12.2 g of 4-dimethylaminopyridine was added, and the resultant was stirred at room temperature. The precipitate formed in this reaction mixture was removed by filtration to obtain a reaction solution.

The thus obtained reaction solution was added to 500 g of ethyl alcohol to generate a precipitate made of a crude polymer. The thus generated crude polymer was separated by filtration and then dissolved in 300 g of GBL to obtain a crude polymer solution. The thus obtained crude polymer solution was added dropwise to 3 kg of water to precipitate a polymer, which was separated by filtration and then vacuum-dried, whereby a powder-form polymer (polyimide A-15) was obtained.

When the molecular weight of the polyimide A-15 was measured by gel permeation chromatography (in terms of standard polystyrene), the values of Mw, Mn, and Mw/Mn were found to be 5,300, 4,200, and 1.28, respectively.

Further, the alicyclic structure content of the polyimide A-15 was 0% by mole, and the imidization rate of the polyimide A-15 was calculated to be 97% by ¹H-NMR

### <Production Example 16> (Synthesis of (A) Polyimide A-16)

A polyimide A-16 was obtained by performing a reaction in the same manner as in Production Example 15, except that the amount of BAFL was changed to 23.2 g, the amount of DCC was changed to 29.5 g, and the amount of HEMA was changed to 18.6 g.

When the molecular weight of the polyimide A-16 was measured by gel permeation chromatography (in terms of standard polystyrene), the values of Mw, Mn, and Mw/Mn were found to be 7,300, 5,000, and 1.46, respectively.

Further, the alicyclic structure content of the polyimide A-16 was 0% by mole, and the imidization rate of the polyimide A-16 was calculated to be 98% by 1H-NMR

### <Production Example 17> (Synthesis of (A) Polyimide A-17)

A polyimide A-17 was obtained by performing a reaction in the same manner as in Production Example 15, except that the amount of BAFL was changed to 26.1 g, the amount of DCC was changed to 22.7 g, and the amount of HEMA was changed to 14.3 g.

When the molecular weight of the polyimide A-17 was measured by gel permeation chromatography (in terms of standard polystyrene), the values of Mw, Mn, and Mw/Mn were found to be 10,800, 6,100, and 1.77, respectively.

Further, the alicyclic structure content of the polyimide A-17 was 0% by mole, and the imidization rate of the polyimide A-17 was calculated to be 100% by ¹H-NMR

### <Production Example 18> (Synthesis of (A) Polyimide A-18)

A polyimide A-18 was obtained by performing a reaction in the same manner as in Production Example 15, except that BAFL was changed to 16.0 g of 2,2′-bis(trifluoromethyl)benzidine (TFMB).

When the molecular weight of the polyimide A-18 was measured by gel permeation chromatography (in terms of standard polystyrene), the values of Mw, Mn, and Mw/Mn were found to be 5,300, 4,200, and 1.28, respectively.

Further, the alicyclic structure content of the polyimide A-18 was 0% by mole, and the imidization rate of the polyimide A-18 was calculated to be 97% by ¹H-NMR

### <Production Example 19> (Synthesis of (A) Polyimide A-19)

A polyimide A-19 was obtained by performing a reaction in the same manner as in Production Example 15, except that BAFL was changed to 25.9 g of 2,2-bis[4-(4-aminophenoxy)phenyl]hexafluoropropane (HFBAPP), and the amount of GBL was changed to 230 g.

When the molecular weight of the polyimide A-19 was measured by gel permeation chromatography (in terms of standard polystyrene), the values of Mw, Mn, and Mw/Mn were found to be 5,700, 4,300, and 1.31, respectively.

Further, the alicylic structure content of the polyimide A-19 was 0% by mole, and the imidization rate of the polyimide A-19 was calculated to be 99% by ¹H-NMR

### <Production Example 20> (Synthesis of (A) Polyimide A-20)

A polyimide A-20 was obtained by performing a reaction in the same manner as in Production Example 15, except that ODPA was changed to 52.0 g of 4,4′-(4,4′-isopropylidenediphenoxy)diphthalic anhydride (BPADA), the amount of BAFL was changed to 17.4 g, the amount of GBL was changed to 280 g, and the amount of toluene was changed to 57 g.

When the molecular weight of the polyimide A-20 was measured by gel permeation chromatography (in terms of standard polystyrene), the values of Mw, Mn, and Mw/Mn were found to be 5,000, 4,000, and 1.25, respectively.

Further, the alicylic structure content of the polyimide A-20 was 0% by mole, and the imidization rate of the polyimide A-20 was calculated to be 98% by ¹H-NMR

### <Production Example 21> (Synthesis of (A) Polyimide A-21)

A polyimide A-21 was obtained by performing a reaction in the same manner as in Production Example 20, except that BAFL was changed to 16.0 g of TFMB.

When the molecular weight of the polyimide A-21 was measured by gel permeation chromatography (in terms of standard polystyrene), the values of Mw, Mn, and Mw/Mn were found to be 5,000, 4,000, and 1.25, respectively.

Further, the alicylic structure content of the polyimide A-21 was 0% by mole, and the imidization rate of the polyimide A-21 was calculated to be 99% by ¹H-NMR

### <Production Example 22> (Synthesis of (A) Polyimide A-22)

A polyimide A-22 was obtained by performing a reaction in the same manner as in Production Example 20, except that BAFL was changed to 14.6 g of 1.3-bis(3-aminophenoxy)benzene (APB).

When the molecular weight of the polyimide A-22 was measured by gel permeation chromatography (in terms of standard polystyrene), the values of Mw, Mn, and Mw/Mn were found to be 4,600, 3,800, and 1.21, respectively.

Further, the alicylic structure content of the polyimide A-22 was 0% by mole, and the imidization rate of the polyimide A-22 was calculated to be 100% by ¹H-NMR

### <Production Example 23> (Synthesis of (A) Polyimide A-23)

A polyimide A-23 was obtained by performing a reaction in the same manner as in Production Example 20, except that BAFL was changed to 14.6 g of 1,4-bis(4-aminophenoxy)benzene (TPE-Q).

When the molecular weight of the polyimide A-23 was measured by gel permeation chromatography (in terms of standard polystyrene), the values of Mw, Mn, and Mw/Mn were found to be 6,100, 4,500, and 1.35, respectively.

Further, the alicyclic structure content of the polyimide A-23 was 0% by mole, and the imidization rate of the polyimide A-23 was calculated to be 99% by 1H-NMR

### <Production Example 24> (Synthesis of (A) Polyimide A-24)

A polyimide A-24 was obtained by performing a reaction in the same manner as in Production Example 20, except that BAFL was changed to 20.5 g of 2,2-bis[4-(4-aminophenoxy)phenyl]propane (BAPP).

When the molecular weight of the polyimide A-24 was measured by gel permeation chromatography (in terms of standard polystyrene), the values of Mw, Mn, and Mw/Mn were found to be 5,700, 4,300, and 1.31, respectively. Further, the alicyclic structure content of the polyimide A-24 was 0% by mole, and the imidization rate of the polyimide A-24 was calculated to be 97% by ¹H-NMR.

### <Production Example 25> (Synthesis of (A) Polyimide A-25)

A polyimide A-25 was obtained by performing a reaction in the same manner as in Production Example 20, except that BAFL was changed to 21.6 g of bis[4-(4-aminophenoxy)phenyl]sulfone (BAPS).

When the molecular weight of the polyimide A-25 was measured by gel permeation chromatography (in terms of standard polystyrene), the values of Mw, Mn, and Mw/Mn were found to be 6,500, 4,700, and 1.38, respectively. Further, the alicyclic structure content of the polyimide A-25 was 0% by mole, and the imidization rate of the polyimide A-25 was calculated to be 96% by ¹H-NMR.

### <Production Example 26> (Synthesis of (A) Polyimide A-26)

A polyimide A-26 was obtained by performing a reaction in the same manner as in Production Example 20, except that BAFL was changed to 25.9 g of HFBAPP.

When the molecular weight of the polyimide A-26 was measured by gel permeation chromatography (in terms of standard polystyrene), the values of Mw, Mn, and Mw/Mn were found to be 6,500, 4,700, and 1.38, respectively. Further, the alicyclic structure content of the polyimide A-26 was 0% by mole, and the imidization rate of the polyimide A-26 was calculated to be 99% by 1H-NMR.

### <Production Example 27> (Synthesis of (A) Polyimide A-27)

A polyimide A-27 was obtained by performing a reaction in the same manner as in Production Example 20, except that BPADA was changed to 44.4 g of 4,4′-(hexafluoroisopropylidene)diphthalic anhydride (6FDA), and BAFL was changed to 14.6 g of TPE-Q.

When the molecular weight of the polyimide A-27 was measured by gel permeation chromatography (in terms of standard polystyrene), the values of Mw, Mn, and Mw/Mn were found to be 6,100, 4,500, and 1.35, respectively.

Further, the alicyclic structure content of the polyimide A-27 was 0% by mole, and the imidization rate of the polyimide A-27 was calculated to be 100% by ¹H-NMR

### <Production Example 28> (Synthesis of (A) Polyimide A-28)

A polyimide A-28 was obtained by performing a reaction in the same manner as in Production Example 15, except that HEMA was changed to 25.5 of 2-hydroxyethyl acrylate (HEA).

When the molecular weight of the polyimide A-28 was measured by gel permeation chromatography (in terms of standard polystyrene), the values of Mw, Mn, and Mw/Mn were found to be 5,000, 4,000, and 1.25, respectively.

Further, the alicyclic structure content of the polyimide A-28 was 0% by mole, and the imidization rate of the polyimide A-28 was calculated to be 98% by ¹H-NMR

### <Production Example 29> (Synthesis of (A) Polyimide A-29)

A polyimide A-29 was obtained by performing a reaction in the same manner as in Production Example 15, except that the amount of BAFL was changed to 28.9 g, the amount of DCC was changed to 15.8 g, and the amount of HEMA was changed to 9.9 g.

When the molecular weight of the polyimide A-29 was measured by gel permeation chromatography (in terms of standard polystyrene), the values of Mw, Mn, and Mw/Mn were found to be 15,900, 9,000, and 1.77, respectively.

Further, the alicyclic structure content of the polyimide A-29 was 0% by mole, and the imidization rate of the polyimide A-29 was calculated to be 98% by ¹H-NMR

### <Production Example 30> (Synthesis of (A) Polyimide A-30)

A polyimide A-30 was obtained by performing a reaction in the same manner as in Production Example 15, except that the amount of BAFL was changed to 13.9 g, the amount of DCC was changed to 36.3 g, and the amount of HEMA was changed to 22.9 g.

When the molecular weight of the polyimide A-30 was measured by gel permeation chromatography (in terms of standard polystyrene), the values of Mw, Mn, and Mw/Mn were found to be 2,800, 2,700, and 1.05, respectively.

Further, the alicyclic structure content of the polyimide A-30 was 0% by mole, and the imidization rate of the polyimide A-30 was calculated to be 100% by ¹H-NMR

### <Synthesis Example 1> (Synthesis of Polyimide A-31)

In a nitrogen-purged three-necked flask to which a Dean-Stark extraction apparatus was attached, 100.0 g of N-methylpyrrolidone (NMP) and 34.9 g (0.1 mol) of 9,9′-bis(4-aminophenyl)fluorene (BAFL) were added and dissolved, and 27.9 g (0.09 mol) of 4,4′-oxydiphthalic dianhydride (ODPA) and 25.0 g of toluene were further added thereto, followed by heating to 180° C.

After confirming that 3.24 g (theoretical amount) of water and 25.0 g of the added toluene were extracted in the Dean-Stark extraction apparatus, heating was stopped, and the resultant was cooled to room temperature.

The thus obtained polymer solution was added dropwise to 3 kg of water to precipitate a polymer, which was separated by filtration and then vacuum-dried, whereby a polyimide A-31 was obtained in the form of powder.

When the molecular weight of the polyimide A-31 was measured by gel permeation chromatography (in terms of standard polystyrene), the values of Mw, Mn, and Mw/Mn were found to be 30,000, 15,000, and 2.00, respectively.

Further, the alicyclic structure content of the polyimide A-31 was 0% by mole, and the imidization rate of the polyimide A-31 was calculated to be 99% by ¹H-NMR

### <Synthesis Example 2> (Synthesis of Polyimide Precursor A-32)

In a 1-L separable flask, 15.6 g (0.05 mol) of ODPA was placed, and 40 g of 7 butyrolactone was added thereto. Next, 13.0 g of HEMA was added, and 7.9 g of pyridine was further added with stirring, after which the resultant was stirred at 40° C. for 5 hours in an oil bath to obtain a reaction mixture. After the completion of reaction, the reaction mixture was allowed to cool to room temperature, and left to stand for 16 hours.

Subsequently, to the resulting reaction mixture, a solution obtained by dissolving 20.2 g of DCC in 25 g of γ-butyrolactone was added over a period of 40 minutes with stirring under ice-cooling, and a suspension obtained by suspending 15.0 g (0.043 mol) of BAFL in 75 g of γ-butyrolactone was then added over a period of 60 minutes. After stirring the resultant at room temperature for 2 hours, 180 g of ethyl alcohol was added and stirred for another hour, after which 140 g of γ-butyrolactone was added and allowed to react. This resulting mixture was filtered, and any precipitate generated in the reaction system was thereby removed to obtain a reaction solution.

The thus obtained reaction solution was added to 0.3 kg of ethyl alcohol to precipitate a crude polymer. The thus precipitated crude polymer was separated by filtration and then dissolved in 150 g of γ-butyrolactone to obtain a crude polymer solution. The thus obtained crude polymer solution was added dropwise to 1.8 kg of water to re-precipitate the polymer. The thus obtained reprecipitate was separated by filtration and then vacuum-dried, whereby a powder-form polymer (polyimide precursor A-32) was obtained.

When the molecular weight of the polyimide precursor A-32 was measured by gel permeation chromatography (in terms of standard polystyrene), the values of Mw, Mn, and Mw/Mn were found to be 17,700, 9,200, and 1.92, respectively.

Further, the alicyclic structure content of the polyimide precursor A-32 was 0% by mole, and the imidization rate of the polyimide precursor A-32 was calculated to be 15% by 1H-NMR.

### <Synthesis Example 3> (Synthesis of Polyimide Precursor A-33)

A polymer A-33 was obtained by performing a reaction in the same manner as in Production Example 32, except that the added amount of BAFL was changed from 15.0 g to 13.1 g.

When the molecular weight of the polymer A-33 was measured by gel permeation chromatography (in terms of standard polystyrene), the values of Mw, Mn, and Mw/Mn were found to be 7,700, 5,200, and 1.48, respectively. Further, the alicyclic structure content of the polyimide precursor A-33 was 0% by mole, and the imidization rate of the polyimide A-33 was calculated to be 18% by ¹H-NMR.

### <Example 1> (Synthesis of Negative Photosensitive Resin Composition)

A negative photosensitive resin composition was prepared by the following method and evaluated.

As a polyimide (A) and a photopolymerization initiator (C), 100 g of A-1 and 8 g of TR-PBG-3057 (trade name, manufactured by Changzhou Tronly New Electronic Materials Co., Ltd., (C-1)), respectively, were dissolved in a mixed solvent of 112 g of 7-butyl lactone (B-1) and 28 g of dimethyl sulfoxide (B-2) as a solvent (B) to obtain a negative photosensitive resin composition. This composition was evaluated in accordance with the above-described methods.

The results thereof are shown in Table 1.

Unless otherwise specified, the units of the values shown in Table 1 are parts by mass.

### Examples 2 to 73 and Comparative Examples 1 to 3

Negative photosensitive resin compositions were prepared and evaluated in the same manner as in Example 1, except that the respective polymers and other additives shown in Table 1 were used. The results thereof are shown in Table 1.

### Evaluation of Value Represented by Equation (I)

The value represented by Equation (I) (Im/Fc×(Mw/Mn)) was calculated for each of the negative photosensitive resin compositions of Examples and Comparative Examples.

The values of Fc and Im/Fc×(Mw/Mn) are shown in Table 2.

TABLE 1

| | | Exam- | Exam- | Exam- | Exam- | Exam- | Exam- | Exam- | Exam- | Exam- | Exam- |
|---|---|---|---|---|---|---|---|---|---|---|---|
| | Number | ple 1 | ple 2 | ple 3 | ple 4 | ple 5 | ple 6 | ple 7 | ple 8 | ple 9 | ple 10 |
| Polymer | A-1 | 100 | 100 | 100 | 100 | 100 | 100 | 100 | 100 | 100 | 100 |
| | A-2 | | | | | | | | | | |
| | A-3 | | | | | | | | | | |
| | A-4 | | | | | | | | | | |
| | A-5 | | | | | | | | | | |
| | A-6 | | | | | | | | | | |
| | A-7 | | | | | | | | | | |
| | A-8 | | | | | | | | | | |
| | A-9 | | | | | | | | | | |
| | A-10 | | | | | | | | | | |
| | A-11 | | | | | | | | | | |
| | A-12 | | | | | | | | | | |
| | A-13 | | | | | | | | | | |
| | A-14 | | | | | | | | | | |
| | A-15 | | | | | | | | | | |
| | A-16 | | | | | | | | | | |
| | A-17 | | | | | | | | | | |
| | A-18 | | | | | | | | | | |
| | A-19 | | | | | | | | | | |
| | A-20 | | | | | | | | | | |
| | A-21 | | | | | | | | | | |
| | A-22 | | | | | | | | | | |
| | A-23 | | | | | | | | | | |
| | A-24 | | | | | | | | | | |
| | A-25 | | | | | | | | | | |
| | A-26 | | | | | | | | | | |
| | A-27 | | | | | | | | | | |
| | A-28 | | | | | | | | | | |
| | A-29 | | | | | | | | | | |
| | A-30 | | | | | | | | | | |
| | A-31 | | | | | | | | | | |
| | A-32 | | | | | | | | | | |
| | A-33 | | | | | | | | | | |
| Solvent | B-1 | 112 | 112 | | | | 112 | 112 | 112 | 112 | 112 |
| | B-2 | 28 | | | | | 28 | 28 | 28 | 28 | 28 |
| | B-3 | | | 140 | | | | | | | |
| | B-4 | | | | | 140 | | | | | |
| | B-5 | | | | 140 | | | | | | |
| | B-6 | | 28 | | | | | | | | |
| Photopolymerization | C-1 | 8 | 8 | 8 | 8 | 8 | 8 | 8 | 8 | 8 | 8 |
| initiator | C-2 | | | | | | | | | | |
| | C-3 | | | | | | | | | | |
| | C-4 | | | | | | | | | | |
| Polymerizable | D-1 | | | | | | | 6 | 8 | 5 | |
| functional | D-2 | | | | | | 20 | | 12 | 15 | 20 |
| group- | D-3 | | | | | | | 14 | | | |
| containing | D-4 | | | | | | | | | | |
| monomer | D-5 | | | | | | | | | | |
| | D-6 | | | | | | | | | | |
| Silane | E-1 | | | | | | | | | | 1.5 |
| coupling agent | E-2 | | | | | | | | | | |
| Organic | F-1 | | | | | | | | | | 1.5 |
| titanium compound | F-2 | | | | | | | | | | |
| Thermal | G-1 | | | | | | | | | | |
| crosslinking | G-2 | | | | | | | | | | |
| agent | G-3 | | | | | | | | | | 10 |
| Rust inhibitor | H-1 | | | | | | | | | | 0.5 |
| | H-2 | | | | | | | | | | |
| | H-3 | | | | | | | | | | |
| | H-4 | | | | | | | | | | |
| Thermal | I-1 | | | | | | | | | | 1 |
| polymerization | | | | | | | | | | | |
| initiator | | | | | | | | | | | |
| Plasticizer | J-1 | | | | | | | | | | 5 |
| Physical | Flatness during | Good | Good | Good | Good | Good | Good | Excel- | Excel- | Excel- | Excel- |
| properties | coating | | | | | | | lent | lent | lent | lent |
| | Post-curing | Good | Good | Good | Good | Good | Excel- | Excel- | Good | Excel- | Excel- |
| | flatness (Fc) | | | | | | lent | lent | | lent | lent |
| | Copper adhesion | Excel- | Excel- | Excel- | Excel- | Excel- | Good | Good | Good | Good | Excel- |
| | | lent | lent | lent | lent | lent | | | | | lent |
| | Copper adhesion after | Excel- | Excel- | Excel- | Excel- | Excel- | Good | Good | Good | Good | Excel- |
| | reliability test | lent | lent | lent | lent | lent | | | | | lent |
| | Chemical resistance | Fair | Fair | Fair | Fair | Fair | Good | Good | Good | Good | Good |
| | Resolution | Fair | Fair | Fair | Fair | Fair | Good | Good | Good | Good | Good |
| | | Exam- | Exam- | Exam- | Exam- | Exam- | Exam- | Exam- | Exam- | Exam- | Exam- |
| | Number | ple 11 | ple 12 | ple 13 | ple 14 | ple 15 | ple 16 | ple 17 | ple 18 | ple 19 | ple 20 |
| Polymer | A-1 | | | | | | | | | | |
| | A-2 | | | | | | | | | | |
| | A-3 | 100 | | | | | | | | | |
| | A-4 | | 100 | | | | | | | | |
| | A-5 | | | 100 | | | | | | | |
| | A-6 | | | | 100 | | | | | | |
| | A-7 | | | | | 100 | | | | | |
| | A-8 | | | | | | 100 | | | | |
| | A-9 | | | | | | | 100 | | | |
| | A-10 | | | | | | | | 100 | | |
| | A-11 | | | | | | | | | 100 | |
| | A-12 | | | | | | | | | | 100 |
| | A-13 | | | | | | | | | | |
| | A-14 | | | | | | | | | | |
| | A-15 | | | | | | | | | | |
| | A-16 | | | | | | | | | | |
| | A-17 | | | | | | | | | | |
| | A-18 | | | | | | | | | | |
| | A-19 | | | | | | | | | | |
| | A-20 | | | | | | | | | | |
| | A-21 | | | | | | | | | | |
| | A-22 | | | | | | | | | | |
| | A-23 | | | | | | | | | | |
| | A-24 | | | | | | | | | | |
| | A-25 | | | | | | | | | | |
| | A-26 | | | | | | | | | | |
| | A-27 | | | | | | | | | | |
| | A-28 | | | | | | | | | | |
| | A-29 | | | | | | | | | | |
| | A-30 | | | | | | | | | | |
| | A-31 | | | | | | | | | | |
| | A-32 | | | | | | | | | | |
| | A-33 | | | | | | | | | | |
| Solvent | B-1 | 112 | 112 | 112 | 112 | 112 | 112 | 112 | 112 | 112 | 112 |
| | B-2 | 28 | 28 | 28 | 28 | 28 | 28 | 28 | 28 | 28 | 28 |
| | B-3 | | | | | | | | | | |
| | B-4 | | | | | | | | | | |
| | B-5 | | | | | | | | | | |
| | B-6 | | | | | | | | | | |
| Photopolymerization | C-1 | 8 | 8 | 8 | 8 | 8 | 8 | 8 | 8 | 8 | 8 |
| initiator | C-2 | | | | | | | | | | |
| | C-3 | | | | | | | | | | |
| | C-4 | | | | | | | | | | |
| Polymerizable | D-1 | | | | | | | | | | |
| functional | D-2 | 20 | 20 | 20 | 20 | 20 | 20 | 20 | 20 | 20 | 20 |
| group- | D-3 | | | | | | | | | | |
| containing | D-4 | | | | | | | | | | |
| monomer | D-5 | | | | | | | | | | |
| | D-6 | | | | | | | | | | |
| Silane | E-1 | 1.5 | 1.5 | 1.5 | 1.5 | 1.5 | 1.5 | 1.5 | 1.5 | 1.5 | 1.5 |
| coupling agent | E-2 | | | | | | | | | | |
| Organic | F-1 | 1.5 | 1.5 | 1.5 | 1.5 | 1.5 | 1.5 | 1.5 | 1.5 | 1.5 | 1.5 |
| titanium compound | F-2 | | | | | | | | | | |
| Thermal | G-1 | | | | | | | | | | |
| crosslinking | G-2 | | | | | | | | | | |
| agent | G-3 | 10 | 10 | 10 | 10 | 10 | 10 | 10 | 10 | 10 | 10 |
| Rust inhibitor | H-1 | 0.5 | 0.5 | 0.5 | 0.5 | 0.5 | 0.5 | 0.5 | 0.5 | 0.5 | 0.5 |
| | H-2 | | | | | | | | | | |
| | H-3 | | | | | | | | | | |
| | H-4 | | | | | | | | | | |
| Thermal | I-1 | 1 | 1 | 1 | 1 | 1 | 1 | 1 | 1 | 1 | 1 |
| polymerization | | | | | | | | | | | |
| initiator | | | | | | | | | | | |
| Plasticizer | J-1 | 5 | 5 | 5 | 5 | 5 | 5 | 5 | 5 | 5 | 5 |
| Physical | Flatness during | Excel- | Excel- | Excel- | Excel- | Excel- | Fair | Fair | Fair | Fair | Fair |
| properties | coating | lent | lent | lent | lent | lent | | | | | |
| | Post-curing | Excel- | Excel- | Excel- | Excel- | Excel- | Fair | Fair | Fair | Fair | Fair |
| | flatness (Fc) | lent | lent | lent | lent | lent | | | | | |
| | Copper adhesion | Excel- | Excel- | Excel- | Excel- | Excel- | Excel- | Excel- | Excel- | Excel- | Excel- |
| | | lent | lent | lent | lent | lent | lent | lent | lent | lent | lent |
| | Copper adhesion after | Excel- | Excel- | Excel- | Excel- | Good | Excel- | Excel- | Excel- | Excel- | Excel- |
| | reliability test | lent | lent | lent | lent | | lent | lent | lent | lent | lent |
| | Chemical resistance | Good | Good | Good | Good | Good | Excel- | Excel- | Excel- | Excel- | Excel- |
| | | | | | | | lent | lent | lent | lent | lent |
| | Resolution | Good | Excel- | Good | Good | Good | Fair | Good | Excel- | Excel- | Excel- |
| | | | lent | | | | | | lent | lent | lent |
| | | Exam- | Exam- | Exam- | Exam- | Exam- | Exam- | Exam- | Exam- | Exam- | Exam- |
| | Number | ple 21 | ple 22 | ple 23 | ple 24 | ple 25 | ple 26 | ple 27 | ple 28 | ple 29 | ple 30 |
| Polymer | A-1 | | | | | | 50 | 70 | 100 | 100 | 100 |
| | A-2 | | | | | | 50 | 30 | | | |
| | A-3 | | | | | | | | | | |
| | A-4 | | | | | | | | | | |
| | A-5 | | | | | | | | | | |
| | A-6 | | | | | | | | | | |
| | A-7 | | | | | | | | | | |
| | A-8 | | | | | | | | | | |
| | A-9 | | | | | | | | | | |
| | A-10 | | | | | | | | | | |
| | A-11 | | | 100 | 100 | 100 | | | | | |
| | A-12 | | | | | | | | | | |
| | A-13 | 100 | | | | | | | | | |
| | A-14 | | 100 | | | | | | | | |
| | A-15 | | | | | | | | | | |
| | A-16 | | | | | | | | | | |
| | A-17 | | | | | | | | | | |
| | A-18 | | | | | | | | | | |
| | A-19 | | | | | | | | | | |
| | A-20 | | | | | | | | | | |
| | A-21 | | | | | | | | | | |
| | A-22 | | | | | | | | | | |
| | A-23 | | | | | | | | | | |
| | A-24 | | | | | | | | | | |
| | A-25 | | | | | | | | | | |
| | A-26 | | | | | | | | | | |
| | A-27 | | | | | | | | | | |
| | A-28 | | | | | | | | | | |
| | A-29 | | | | | | | | | | |
| | A-30 | | | | | | | | | | |
| | A-31 | | | | | | | | | | |
| | A-32 | | | | | | | | | | |
| | A-33 | | | | | | | | | | |
| Solvent | B-1 | 112 | 112 | 112 | 112 | 112 | 112 | 112 | 112 | 112 | 112 |
| | B-2 | 28 | 28 | 28 | 28 | 28 | 28 | 28 | 28 | 28 | 28 |
| | B-3 | | | | | | | | | | |
| | B-4 | | | | | | | | | | |
| | B-5 | | | | | | | | | | |
| | B-6 | | | | | | | | | | |
| Photopolymerization | C-1 | 8 | 8 | 8 | 8 | 8 | 8 | 8 | | | 10 |
| initiator | C-2 | | | | | | | | 8 | | |
| | C-3 | | | | | | | | | 8 | |
| | C-4 | | | | | | | | | | |
| Polymerizable | D-1 | | | | | | | | | | |
| functional | D-2 | 20 | 20 | 10 | 14 | 19 | 20 | 20 | 20 | 20 | 20 |
| group- | D-3 | | | | | | | | | | |
| containing | D-4 | | | | | | | | | | |
| monomer | D-5 | | | | | | | | | | |
| | D-6 | | | 10 | 6 | 1 | | | | | |
| Silane | E-1 | 1.5 | 1.5 | 1.5 | 1.5 | 1.5 | 1.5 | 1.5 | 1.5 | 1.5 | 1.5 |
| coupling agent | E-2 | | | | | | | | | | |
| Organic | F-1 | 1.5 | 1.5 | 1.5 | 1.5 | 1.5 | 1.5 | 1.5 | 1.5 | 1.5 | 1.5 |
| titanium compound | F-2 | | | | | | | | | | |
| Thermal | G-1 | | | | | | | | | | |
| crosslinking | G-2 | | | | | | | | | | |
| agent | G-3 | 10 | 10 | 10 | 10 | 10 | 10 | 10 | 10 | 10 | 10 |
| Rust inhibitor | H-1 | 0.5 | 0.5 | 0.5 | 0.5 | 0.5 | 0.5 | 0.5 | 0.5 | 0.5 | 0.5 |
| | H-2 | | | | | | | | | | |
| | H-3 | | | | | | | | | | |
| | H-4 | | | | | | | | | | |
| Thermal | I-1 | 1 | 1 | 1 | 1 | 1 | 1 | 1 | 1 | 1 | 1 |
| polymerization | | | | | | | | | | | |
| initiator | | | | | | | | | | | |
| Plasticizer | J-1 | 5 | 5 | 5 | 5 | 5 | 5 | 5 | 5 | 5 | 5 |
| Physical | Flatness during | Fair | Fait | Good | Good | Fair | Excel- | Excel- | Excel- | Excel- | Excel- |
| properties | coating | | | | | | lent | lent | lent | lent | lent |
| | Post-curing | Fair | Fair | Fair | Good | Fair | Excel- | Excel- | Excel- | Excel- | Excel- |
| | flatness (Fc) | | | | | | lent | lent | lent | lent | lent |
| | Copper adhesion | Excel- | Excel- | Excel- | Excel- | Excel- | Excel- | Excel- | Excel- | Excel- | Excel- |
| | | lent | lent | lent | lent | lent | lent | lent | lent | lent | lent |
| | Copper adhesion after | Excel- | Excel- | Excel- | Excel- | Excel- | Excel- | Excel- | Excel- | Excel- | Excel- |
| | reliability test | lent | lent | lent | lent | lent | lent | lent | lent | lent | lent |
| | Chemical resistance | Excel- | Excel- | Excel- | Excel- | Excel- | Good | Good | Good | Good | Good |
| | | lent | lent | lent | lent | lent | | | | | |
| | Resolution | Fair | Good | Good | Good | Good | Good | Good | Good | Good | Excel- |
| | | | | | | | | | | | lent |
| | | Exam- | Exam- | Exam- | Exam- | Exam- | Exam- | Exam- | Exam- | Exam- | Exam- |
| | Number | ple 31 | ple 32 | ple 33 | ple 34 | ple 35 | ple 36 | ple 37 | ple 38 | ple 39 | ple 40 |
| Polymer | A-1 | 100 | 100 | 100 | 100 | 100 | 100 | 100 | 100 | 100 | 100 |
| | A-2 | | | | | | | | | | |
| | A-3 | | | | | | | | | | |
| | A-4 | | | | | | | | | | |
| | A-5 | | | | | | | | | | |
| | A-6 | | | | | | | | | | |
| | A-7 | | | | | | | | | | |
| | A-8 | | | | | | | | | | |
| | A-9 | | | | | | | | | | |
| | A-10 | | | | | | | | | | |
| | A-11 | | | | | | | | | | |
| | A-12 | | | | | | | | | | |
| | A-13 | | | | | | | | | | |
| | A-14 | | | | | | | | | | |
| | A-15 | | | | | | | | | | |
| | A-16 | | | | | | | | | | |
| | A-17 | | | | | | | | | | |
| | A-18 | | | | | | | | | | |
| | A-19 | | | | | | | | | | |
| | A-20 | | | | | | | | | | |
| | A-21 | | | | | | | | | | |
| | A-22 | | | | | | | | | | |
| | A-23 | | | | | | | | | | |
| | A-24 | | | | | | | | | | |
| | A-25 | | | | | | | | | | |
| | A-26 | | | | | | | | | | |
| | A-27 | | | | | | | | | | |
| | A-28 | | | | | | | | | | |
| | A-29 | | | | | | | | | | |
| | A-30 | | | | | | | | | | |
| | A-31 | | | | | | | | | | |
| | A-32 | | | | | | | | | | |
| | A-33 | | | | | | | | | | |
| Solvent | B-1 | 112 | 112 | 112 | 112 | 112 | 112 | 112 | 112 | 112 | 112 |
| | B-2 | 28 | 28 | 28 | 28 | 28 | 28 | 28 | 28 | 28 | 28 |
| | B-3 | | | | | | | | | | |
| | B-4 | | | | | | | | | | |
| | B-5 | | | | | | | | | | |
| | B-6 | | | | | | | | | | |
| Photopolymerization | C-1 | 6 | 4 | 8 | 8 | 8 | 8 | 8 | 8 | 8 | 8 |
| initiator | C-2 | | | | | | | | | | |
| | C-3 | | | | | | | | | | |
| | C-4 | | | | | | | | | | |
| Polymerizable | D-1 | | | 20 | | | 10 | 10 | 10 | | |
| functional | D-2 | 20 | 20 | | | | 10 | | | 10 | 10 |
| group- | D-3 | | | | 20 | | | 10 | | 10 | |
| containing | D-4 | | | | | 20 | | | 10 | | 10 |
| monomer | D-5 | | | | | | | | | | |
| | D-6 | | | | | | | | | | |
| Silane | E-1 | 1.5 | 1.5 | 1.5 | 1.5 | 1.5 | 1.5 | 1.5 | 1.5 | 1.5 | 1.5 |
| coupling agent | E-2 | | | | | | | | | | |
| Organic | F-1 | 1.5 | 1.5 | 1.5 | 1.5 | 1.5 | 1.5 | 1.5 | 1.5 | 1.5 | 1.5 |
| titanium compound | F-2 | | | | | | | | | | |
| Thermal | G-1 | | | | | | | | | | |
| crosslinking | G-2 | | | | | | | | | | |
| agent | G-3 | 10 | 10 | 10 | 10 | 10 | 10 | 10 | 10 | 10 | 10 |
| Rust inhibitor | H-1 | 0.5 | 0.5 | 0.5 | 0.5 | 0.5 | 0.5 | 0.5 | 0.5 | 0.5 | 0.5 |
| | H-2 | | | | | | | | | | |
| | H-3 | | | | | | | | | | |
| | H-4 | | | | | | | | | | |
| Thermal | I-1 | 1 | 1 | 1 | 1 | 1 | 1 | 1 | 1 | 1 | 1 |
| polymerization | | | | | | | | | | | |
| initiator | | | | | | | | | | | |
| Plasticizer | J-1 | 5 | 5 | 5 | 5 | 5 | 5 | 5 | 5 | 5 | 5 |
| Physical | Flatness during | Excel- | Excel- | Excel- | Excel- | Excel- | Excel- | Excel- | Excel- | Excel- | Excel- |
| properties | coating | lent | lent | lent | lent | lent | lent | lent | lent | lent | lent |
| | Post-curing | Excel- | Excel- | Good | Excel- | Excel- | Good | Excel- | Excel- | Excel- | Excel- |
| | flatness (Fc) | lent | lent | | lent | lent | | lent | lent | lent | lent |
| | Copper adhesion | Excel- | Excel- | Excel- | Excel- | Excel- | Excel- | Excel- | Excel- | Excel- | Excel- |
| | | lent | lent | lent | lent | lent | lent | lent | lent | lent | lent |
| | Copper adhesion after | Excel- | Excel- | Excel- | Excel- | Excel- | Excel- | Excel- | Excel- | Excel- | Excel- |
| | reliability test | lent | lent | lent | lent | lent | lent | lent | lent | lent | lent |
| | Chemical resistance | Good | Good | Fair | Excel- | Excel- | Fair | Good | Good | Excel- | Excel- |
| | | | | | lent | lent | | | | lent | lent |
| | Resolution | Good | Fair | Good | Good | Good | Good | Good | Good | Good | Good |
| | | Exam- | Exam- | Exam- | Exam- | Exam- | Exam- | Exam- | Exam- | Exam- | Exam- |
| | Number | ple 41 | ple 42 | ple 43 | ple 44 | ple 45 | ple 46 | ple 47 | ple 48 | ple 49 | ple 50 |
| Polymer | A-1 | 100 | 100 | 100 | 100 | 100 | 100 | 100 | 100 | 100 | 100 |
| | A-2 | | | | | | | | | | |
| | A-3 | | | | | | | | | | |
| | A-4 | | | | | | | | | | |
| | A-5 | | | | | | | | | | |
| | A-6 | | | | | | | | | | |
| | A-7 | | | | | | | | | | |
| | A-8 | | | | | | | | | | |
| | A-9 | | | | | | | | | | |
| | A-10 | | | | | | | | | | |
| | A-11 | | | | | | | | | | |
| | A-12 | | | | | | | | | | |
| | A-13 | | | | | | | | | | |
| | A-14 | | | | | | | | | | |
| | A-15 | | | | | | | | | | |
| | A-16 | | | | | | | | | | |
| | A-17 | | | | | | | | | | |
| | A-18 | | | | | | | | | | |
| | A-19 | | | | | | | | | | |
| | A-20 | | | | | | | | | | |
| | A-21 | | | | | | | | | | |
| | A-22 | | | | | | | | | | |
| | A-23 | | | | | | | | | | |
| | A-24 | | | | | | | | | | |
| | A-25 | | | | | | | | | | |
| | A-26 | | | | | | | | | | |
| | A-27 | | | | | | | | | | |
| | A-28 | | | | | | | | | | |
| | A-29 | | | | | | | | | | |
| | A-30 | | | | | | | | | | |
| | A-31 | | | | | | | | | | |
| | A-32 | | | | | | | | | | |
| | A-33 | | | | | | | | | | |
| Solvent | B-1 | 112 | 112 | 112 | 112 | 112 | 112 | 112 | 112 | 112 | 112 |
| | B-2 | 28 | 28 | 28 | 28 | 28 | 28 | 28 | 28 | 28 | 28 |
| | B-3 | | | | | | | | | | |
| | B-4 | | | | | | | | | | |
| | B-5 | | | | | | | | | | |
| | B-6 | | | | | | | | | | |
| Photopolymerization | C-1 | 8 | 8 | 4 | 8 | 8 | 8 | 8 | 8 | 8 | 8 |
| initiator | C-2 | | | | | | | | | | |
| | C-3 | | | | | | | | | | |
| | C-4 | | | | | | | | | | |
| Polymerizable | D-1 | | | | | | | | | | |
| functional | D-2 | 40 | 20 | 100 | 20 | 20 | 20 | 20 | 20 | 20 | 20 |
| group- | D-3 | | 20 | | | | | | | | |
| containing | D-4 | | | | | | | | | | |
| monomer | D-5 | | | | | | | | | | |
| | D-6 | | | | | | | | | | |
| Silane | E-1 | 1.5 | 1.5 | 1.5 | | 1.5 | 1.5 | 1.5 | 1.5 | 1.5 | 1.5 |
| coupling agent | E-2 | | | | | | | | | | |
| Organic | F-1 | 1.5 | 1.5 | 1.5 | 1.5 | | 1.5 | 1.5 | 1.5 | 1.5 | 1.5 |
| titanium compound | F-2 | | | | | | | | | | |
| Thermal | G-1 | | | | | | | 10 | | 10 | |
| crosslinking | G-2 | | | | | | | | 10 | | |
| agent | G-3 | 10 | 10 | 10 | 10 | 10 | | | | | 20 |
| Rust inhibitor | H-1 | 0.5 | 0.5 | 0.5 | 0.5 | 0.5 | 0.5 | 0.5 | 0.5 | 0.5 | 0.5 |
| | H-2 | | | | | | | | | | |
| | H-3 | | | | | | | | | | |
| | H-4 | | | | | | | | | | |
| Thermal | I-1 | 1 | 1 | 1 | 1 | 1 | 1 | 1 | 1 | 1 | 1 |
| polymerization | | | | | | | | | | | |
| initiator | | | | | | | | | | | |
| Plasticizer | J-1 | 5 | 5 | 5 | 5 | 5 | 5 | 5 | 5 | 5 | 5 |
| Physical | Flatness during | Excel- | Excel- | Excel- | Excel- | Excel- | Excel- | Excel- | Excel- | Excel- | Excel- |
| properties | coating | lent | lent | lent | lent | lent | lent | lent | lent | lent | lent |
| | Post-curing | Excel- | Excel- | Excel- | Excel- | Excel- | Good | Excel- | Excel- | Excel- | Excel- |
| | flatness (Fc) | lent | lent | lent | lent | lent | | lent | lent | lent | lent |
| | Copper adhesion | Excel- | Excel- | Fair | Excel- | Excel- | Excel- | Excel- | Excel- | Excel- | Excel- |
| | | lent | lent | | lent | lent | lent | lent | lent | lent | lent |
| | Copper adhesion after | Good | Good | Fair | Good | Excel- | Excel- | Excel- | Excel- | Excel- | Excel- |
| | reliability test | | | | | lent | lent | lent | lent | lent | lent |
| | Chemical resistance | Excel- | Excel- | Excel- | Good | Fair | Fair | Good | Good | Good | Good |
| | | lent | lent | lent | | | | | | | |
| | Resolution | Excel- | Excel- | Good | Good | Good | Good | Good | Good | Good | Fair |
| | | lent | lent | | | | | | | | |
| | | Exam- | Exam- | Exam- | Exam- | Exam- | Exam- | Exam- | Exam- | Exam- | Exam- |
| | Number | ple 51 | ple 52 | ple 53 | ple 54 | ple 55 | ple 56 | ple 57 | ple 58 | ple 59 | ple 60 |
| Polymer | A-1 | 100 | 100 | 100 | 100 | 100 | 100 | 100 | | | |
| | A-2 | | | | | | | | | | |
| | A-3 | | | | | | | | | | |
| | A-4 | | | | | | | | | | |
| | A-5 | | | | | | | | | | |
| | A-6 | | | | | | | | | | |
| | A-7 | | | | | | | | | | |
| | A-8 | | | | | | | | | | |
| | A-9 | | | | | | | | | | |
| | A-10 | | | | | | | | | | |
| | A-11 | | | | | | | | | | |
| | A-12 | | | | | | | | | | |
| | A-13 | | | | | | | | | | |
| | A-14 | | | | | | | | | | |
| | A-15 | | | | | | | | 100 | | |
| | A-16 | | | | | | | | | 100 | |
| | A-17 | | | | | | | | | | 100 |
| | A-18 | | | | | | | | | | |
| | A-19 | | | | | | | | | | |
| | A-20 | | | | | | | | | | |
| | A-21 | | | | | | | | | | |
| | A-22 | | | | | | | | | | |
| | A-23 | | | | | | | | | | |
| | A-24 | | | | | | | | | | |
| | A-25 | | | | | | | | | | |
| | A-26 | | | | | | | | | | |
| | A-27 | | | | | | | | | | |
| | A-28 | | | | | | | | | | |
| | A-29 | | | | | | | | | | |
| | A-30 | | | | | | | | | | |
| | A-31 | | | | | | | | | | |
| | A-32 | | | | | | | | | | |
| | A-33 | | | | | | | | | | |
| Solvent | B-1 | 112 | 112 | 112 | 112 | 112 | 112 | 112 | 112 | 112 | 112 |
| | B-2 | 28 | 28 | 28 | 28 | 28 | 28 | 28 | 28 | 28 | 28 |
| | B-3 | | | | | | | | | | |
| | B-4 | | | | | | | | | | |
| | B-5 | | | | | | | | | | |
| | B-6 | | | | | | | | | | |
| Photopolymerization | C-1 | 8 | 8 | 8 | 8 | 8 | 8 | 8 | 2 | 2 | 2 |
| initiator | C-2 | | | | | | | | | | |
| | C-3 | | | | | | | | | | |
| | C-4 | | | | | | | | | | |
| Polymerizable | D-1 | | | | | | | | | | |
| functional | D-2 | 20 | 20 | 20 | 20 | 20 | 20 | 20 | | | |
| group- | D-3 | | | | | | | | | | |
| containing | D-4 | | | | | | | | | | |
| monomer | D-5 | | | | | | | | 40 | 40 | 40 |
| | D-6 | | | | | | | | | | |
| Silane | E-1 | 1.5 | 1.5 | 1.5 | 1.5 | 1.5 | 1.5 | 1.5 | 1.5 | 1.5 | 1.5 |
| coupling agent | E-2 | | | | | | | | | | |
| Organic | F-1 | 1.5 | 1.5 | 1.5 | 1.5 | 1.5 | 1.5 | 1.5 | | | |
| titanium compound | F-2 | | | | | | | | 1.5 | 1.5 | 1.5 |
| Thermal | G-1 | | | | | | | | | | |
| crosslinking | G-2 | | | | | | | | | | |
| agent | G-3 | 10 | 10 | 10 | 10 | 10 | 10 | 10 | | | |
| Rust inhibitor | H-1 | | | | | | 0.5 | 0.5 | 0.5 | 0.5 | 0.5 |
| | H-2 | | 0.5 | 3 | | | | | | | |
| | H-3 | | | | 0.5 | | | | | | |
| | H-4 | | | | | 0.5 | | | | | |
| Thermal | I-1 | 1 | 1 | 1 | 1 | 1 | | 1 | | | |
| polymerization | | | | | | | | | | | |
| initiator | | | | | | | | | | | |
| Plasticizer | J-1 | 5 | 5 | 5 | 5 | 5 | 5 | | | | |
| Physical | Flatness during | Excel- | Excel- | Excel- | Excel- | Excel- | Excel- | Good | Excel- | Good | Fair |
| properties | coating | lent | lent | lent | lent | lent | lent | | lent | | |
| | Post-curing | Excel- | Excel- | Excel- | Excel- | Excel- | Good | Good | Excel- | Good | Fair |
| | flatness (Fc) | lent | lent | lent | lent | lent | | | lent | | |
| | Copper adhesion | Good | Excel- | Excel- | Excel- | Excel- | Excel- | Excel- | Excel- | Excel- | Excel- |
| | | | lent | lent | lent | lent | lent | lent | lent | lent | lent |
| | Copper adhesion after | Fair | Good | Excel- | Excel- | Excel- | Excel- | Excel- | Excel- | Excel- | Excel- |
| | reliability test | | | lent | lent | lent | lent | lent | lent | lent | lent |
| | Chemical resistance | Good | Good | Good | Good | Good | Fair | Good | Excel- | Excel- | Excel- |
| | | | | | | | | | lent | lent | lent |
| | Resolution | Good | Good | Good | Good | Good | Good | Good | Good | Good | Good |

| | | Example | Example | Example | Example | Example | Example | Example | Example |
|---|---|---|---|---|---|---|---|---|---|
| | Number | 61 | 62 | 63 | 64 | 65 | 66 | 67 | 68 |
| Polymer | A-1 | | | | | | | | |
| | A-2 | | | | | | | | |
| | A-3 | | | | | | | | |
| | A-4 | | | | | | | | |
| | A-5 | | | | | | | | |
| | A-6 | | | | | | | | |
| | A-7 | | | | | | | | |
| | A-8 | | | | | | | | |
| | A-9 | | | | | | | | |
| | A-10 | | | | | | | | |
| | A-11 | | | | | | | | |
| | A-12 | | | | | | | | |
| | A-13 | | | | | | | | |
| | A-14 | | | | | | | | |
| | A-15 | | | | | | | | |
| | A-16 | | | | | | | | |
| | A-17 | | | | | | | | |
| | A-18 | 100 | | | | | | | |
| | A-19 | | 100 | | | | | | |
| | A-20 | | | 100 | | | | | |
| | A-21 | | | | 100 | | | | |
| | A-22 | | | | | 100 | | | |
| | A-23 | | | | | | 100 | | |
| | A-24 | | | | | | | 100 | |
| | A-25 | | | | | | | | 100 |
| | A-26 | | | | | | | | |
| | A-27 | | | | | | | | |
| | A-28 | | | | | | | | |
| | A-29 | | | | | | | | |
| | A-30 | | | | | | | | |
| | A-31 | | | | | | | | |
| | A-32 | | | | | | | | |
| | A-33 | | | | | | | | |
| Solvent | B-1 | 112 | 112 | 112 | 112 | 112 | 112 | 112 | 112 |
| | B-2 | 28 | 28 | 28 | 28 | 28 | 28 | 28 | 28 |
| | B-3 | | | | | | | | |
| | B-4 | | | | | | | | |
| | B-5 | | | | | | | | |
| | B-6 | | | | | | | | |
| Photopolymerization | C-1 | 2 | 2 | 2 | 2 | 2 | 2 | 2 | 2 |
| initiator | C-2 | | | | | | | | |
| | C-3 | | | | | | | | |
| | C-4 | | | | | | | | |
| Polymerizable | D-1 | | | | | | | | |
| functional | D-2 | | | | | | | | |
| group- | D-3 | | | | | | | | |
| containing | D-4 | | | | | | | | |
| monomer | D-5 | 40 | 40 | 40 | 40 | 40 | 40 | 40 | 40 |
| | D-6 | | | | | | | | |
| Silane | E-1 | 1.5 | 1.5 | 1.5 | 1.5 | 1.5 | 1.5 | 1.5 | 1.5 |
| coupling agent | E-2 | | | | | | | | |
| Organic | F-1 | | | | | | | | |
| titanium compound | F-2 | 1.5 | 1.5 | 1.5 | 1.5 | 1.5 | 1.5 | 1.5 | 1.5 |
| Thermal | G-1 | | | | | | | | |
| crosslinking | G-2 | | | | | | | | |
| agent | G-3 | | | | | | | | |
| Rust inhibitor | H-1 | 0.5 | 0.5 | 0.5 | 0.5 | 0.5 | 0.5 | 0.5 | 0.5 |
| | H-2 | | | | | | | | |
| | H-3 | | | | | | | | |
| | H-4 | | | | | | | | |
| Thermal | I-1 | | | | | | | | |
| polymerization | | | | | | | | | |
| initiator | | | | | | | | | |
| Plasticizer | J-1 | | | | | | | | |
| Physical | Flatness during | Good | Good | Excellent | Excellent | Excellent | Excellent | Excellent | Excellent |
| properties | coating | | | | | | | | |
| | Post-curing | Good | Good | Excellent | Excellent | Excellent | Excellent | Excellent | Excellent |
| | flatness (Fc) | | | | | | | | |
| | Copper adhesion | Excellent | Excellent | Excellent | Excellent | Excellent | Excellent | Excellent | Excellent |
| | Copper adhesion after | Excellent | Excellent | Excellent | Excellent | Excellent | Excellent | Excellent | Excellent |
| | reliability test | | | | | | | | |
| | Chemical resistance | Fair | Fair | Excellent | Fair | Excellent | Excellent | Excellent | Excellent |
| | Resolution | Good | Good | Good | Good | Good | Good | Good | Good |

| | | | | | | | Compar- | Compar- | Compar- |
|---|---|---|---|---|---|---|---|---|---|
| | | Example | Example | Example | Example | Example | ative | ative | ative |
| | Number | 69 | 70 | 71 | 72 | 73 | Example 1 | Example 2 | Example 3 |
| Polymer | A-1 | | | | | | | | |
| | A-2 | | | | | | | | |
| | A-3 | | | | | | | | |
| | A-4 | | | | | | | | |
| | A-5 | | | | | | | | |
| | A-6 | | | | | | | | |
| | A-7 | | | | | | | | |
| | A-8 | | | | | | | | |
| | A-9 | | | | | | | | |
| | A-10 | | | | | | | | |
| | A-11 | | | | | | | | |
| | A-12 | | | | | | | | |
| | A-13 | | | | | | | | |
| | A-14 | | | | | | | | |
| | A-15 | | | | | | | | |
| | A-16 | | | | | | | | |
| | A-17 | | | | | | | | |
| | A-18 | | | | | | | | |
| | A-19 | | | | | | | | |
| | A-20 | | | | | | | | |
| | A-21 | | | | | | | | |
| | A-22 | | | | | | | | |
| | A-23 | | | | | | | | |
| | A-24 | | | | | | | | |
| | A-25 | | | | | | | | |
| | A-26 | 100 | | | | | | | |
| | A-27 | | 100 | | | | | | |
| | A-28 | | | 100 | | | | | |
| | A-29 | | | | 100 | | | | |
| | A-30 | | | | | 100 | | | |
| | A-31 | | | | | | 100 | | |
| | A-32 | | | | | | | 100 | |
| | A-33 | | | | | | | | 100 |
| Solvent | B-1 | 112 | 112 | 112 | 112 | 112 | 112 | 112 | 112 |
| | B-2 | 28 | 28 | 28 | 28 | 28 | 28 | 28 | 28 |
| | B-3 | | | | | | | | |
| | B-4 | | | | | | | | |
| | B-5 | | | | | | | | |
| | B-6 | | | | | | | | |
| Photopolymerization | C-1 | 2 | 2 | 2 | 2 | 2 | 8 | 8 | 8 |
| initiator | C-2 | | | | | | | | |
| | C-3 | | | | | | | | |
| | C-4 | | | | | | | | |
| Polymerizable | D-1 | | | | | | | | |
| functional | D-2 | | | | | | 20 | 20 | 20 |
| group- | D-3 | | | | | | | | |
| containing | D-4 | | | | | | | | |
| monomer | D-5 | 40 | 40 | 40 | 40 | 40 | | | |
| | D-6 | | | | | | | | |
| Silane | E-1 | 1.5 | 1.5 | 1.5 | 1.5 | 1.5 | 1.5 | 1.5 | 1.5 |
| coupling agent | E-2 | | | | | | | | |
| Organic | F-1 | | | | | | 1.5 | 1.5 | 1.5 |
| titanium compound | F-2 | 1.5 | 1.5 | 1.5 | 1.5 | 1.5 | | | |
| Thermal | G-1 | | | | | | | | |
| crosslinking | G-2 | | | | | | | | |
| agent | G-3 | | | | | | 10 | 10 | 10 |
| Rust inhibitor | H-1 | 0.5 | 0.5 | 0.5 | 0.5 | 0.5 | 0.5 | 0.5 | 0.5 |
| | H-2 | | | | | | | | |
| | H-3 | | | | | | | | |
| | H-4 | | | | | | | | |
| Thermal | I-1 | | | | | | 1 | 1 | 1 |
| polymerization | | | | | | | | | |
| initiator | | | | | | | | | |
| Plasticizer | J-1 | | | | | | 5 | 5 | 5 |
| Physical | Flatness during | Excellent | Excellent | Excellent | Fair | Excellent | Poor | Good | Excellent |
| properties | coating | | | | | | | | |
| | Post-curing | Excellent | Excellent | Excellent | Fair | Excellent | Poor | Poor | Poor |
| | flatness (Fc) | | | | | | | | |
| | Copper adhesion | Excellent | Excellent | Excellent | Excellent | Good | Good | Poor | Poor |
| | Copper adhesion after | Excellent | Excellent | Excellent | Excellent | Good | Fair | Poor | Poor |
| | reliability test | | | | | | | | |
| | Chemical resistance | Fair | Excellent | Excellent | Excellent | Excellent | Fair | Fair | Poor |
| | Resolution | Good | Good | Good | Fair | Good | Fair | Good | Excellent |

TABLE 2

| | Number | | | | | | | |
|---|---|---|---|---|---|---|---|---|
| | Example | Example | Example | Example | Example | Example | Example | Example |
| | 1 | 2 | 3 | 4 | 5 | 6 | 7 | 8 |
| Fc | 0.4 | 0.4 | 0.4 | 0.4 | 0.4 | 0.3 | 0.3 | 0.4 |
| Im/Fc × (Mw/Mn) | 190 | 190 | 190 | 190 | 190 | 253 | 253 | 190 |

| | Number | | | | | | |
|---|---|---|---|---|---|---|---|
| | Example | Example | Example | Example | Example | Example | Example |
| | 9 | 10 | 11 | 12 | 13 | 14 | 15 |
| Fc | 0.3 | 0.2 | 0.2 | 0.2 | 0.2 | 0.2 | 0.2 |
| Im/Fc × (Mw/Mn) | 253 | 380 | 378 | 392 | 419 | 424 | 405 |

| | Number | | | | | | | |
|---|---|---|---|---|---|---|---|---|
| | Example | Example | Example | Example | Example | Example | Example | Example |
| | 16 | 17 | 18 | 19 | 20 | 21 | 22 | 23 |
| Fc | 0.6 | 0.6 | 0.6 | 0.6 | 0.6 | 0.6 | 0.6 | 0.6 |
| Im/Fc × (Mw/Mn) | 92 | 92 | 95 | 95 | 96 | 104 | 108 | 95 |

| | Number | | | | | | |
|---|---|---|---|---|---|---|---|
| | Example | Example | Example | Example | Example | Example | Example |
| | 24 | 25 | 26 | 27 | 28 | 29 | 30 |
| Fc | 0.4 | 0.6 | 0.3 | 0.3 | 0.3 | 0.3 | 0.3 |
| Im/Fc × (Mw/Mn) | 142 | 95 | 253 | 253 | 253 | 253 | 253 |

| | Number | | | | | | | |
|---|---|---|---|---|---|---|---|---|
| | Example | Example | Example | Example | Example | Example | Example | Example |
| | 31 | 32 | 33 | 34 | 35 | 36 | 37 | 38 |
| Fc | 0.3 | 0.3 | 0.4 | 0.3 | 0.3 | 0.4 | 0.3 | 0.3 |
| Im/Fc × (Mw/Mn) | 253 | 253 | 190 | 253 | 253 | 190 | 253 | 253 |

| | Number | | | | | | |
|---|---|---|---|---|---|---|---|
| | Example | Example | Example | Example | Example | Example | Example |
| | 39 | 40 | 41 | 42 | 43 | 44 | 45 |
| Fc | 0.3 | 0.3 | 0.15 | 0.15 | 0.1 | 0.3 | 0.3 |
| Im/Fc × (Mw/Mn) | 253 | 253 | 506 | 506 | 760 | 253 | 253 |

| | Number | | | | | | | |
|---|---|---|---|---|---|---|---|---|
| | Example | Example | Example | Example | Example | Example | Example | Example |
| | 46 | 47 | 48 | 49 | 50 | 51 | 52 | 53 |
| Fc | 0.4 | 0.3 | 0.3 | 0.3 | 0.3 | 0.3 | 0.3 | 0.3 |
| Im/Fc × (Mw/Mn) | 190 | 253 | 253 | 253 | 253 | 253 | 253 | 253 |

| | Number | | | | | | |
|---|---|---|---|---|---|---|---|
| | Example | Example | Example | Example | Example | Example | Example |
| | 54 | 55 | 56 | 57 | 58 | 59 | 60 |
| Fc | 0.3 | 0.3 | 0.4 | 0.4 | 0.15 | 0.38 | 0.56 |
| Im/Fc × (Mw/Mn) | 253 | 253 | 190 | 190 | 513 | 177 | 116 |

| | Number | | | | | | | | |
|---|---|---|---|---|---|---|---|---|---|
| | Example | Example | Example | Example | Example | Example | Example | Example | Example |
| | 61 | 62 | 63 | 64 | 65 | 66 | 67 | 68 | 69 |
| Fc | 0.4 | 0.4 | 0.2 | 0.2 | 0.2 | 0.25 | 0.25 | 0.25 | 0.25 |
| Im/Fc × (Mw/Mn) | 192 | 186 | 392 | 396 | 413 | 291 | 292 | 278 | 287 |

| | Number | | | | | | |
|---|---|---|---|---|---|---|---|
| | Example | Example | Example | Example | Comparative | Comparative | Comparative |
| | 70 | 71 | 72 | 73 | Example 1 | Example 2 | Example 3 |
| Fc | 0.25 | 0.25 | 0.6 | 0.3 | 0.7 | 0.7 | 0.7 |
| Im/Fc × (Mw/Mn) | 294 | 314 | 98 | 321 | 71 | 12 | 17 |

B-1: γ-butyrolactone
B-2: dimethyl sulfoxide
B-3: N-methyl-2-pyrrolidone
BA: 3-methoxy-N,N-dimethylpropanamide
B-5: 1,3-dimethyl-2-imidazolidinone
B-6: ethyl lactate
C-1: product name: TR-PBG-3057 (manufactured by Changzhou Tronly New Electronic Materials Co., Ltd.)
C-2: product name: TR-PBG-304 (manufactured by Changzhou Tronly New Electronic Materials Co., Ltd.)
C-3: product name: NCI-831 (manufactured by ADEKA Corporation)
C-4: diphenyl(2,4,6-trimethylbenzoyl)phosphine oxide
D-1: 2-hydroxyethyl methacrylate
D-2: tetraethylene glycol dimethacrylate
D-3: tris-(2-acryloxyethyl) isocyanurate
D-4: pentaerythritol tetraacrylate
D-5: tris-(2-hydroxyethyl)isocyanurate acrylate
D-6: methoxy-polyethylene glycol monomethacrylate (product name: PME-400, manufactured by NOF Corporation)
E-1: N-phenyl-3-aminopropyltrimethoxysilane
F-1: titanium (IV) oxide acetylacetonate
F-2: diisopropoxy titanium bis(ethylacetate)
G-1: 4-hydroxybutyl acrylate glycidyl ether
G-2: 2,4,6-tris[bis(methoxymethyl)amino]-1,3,5-triazine
G-3: 1,3,4,6-tetrakis(methoxymethyl)glycoluril
H-1: 8-azaadenine
H-2: compound of the following structure

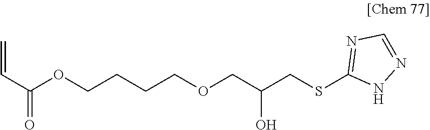 [SMILES: C=CC(=O)OCCCCOCC(O)CSc1ncn[nH]1]

H-3: 5-amino-1H-tetrazole
H-4: 3-mercapto-1,2,4-triazole
I-1: dicumyl peroxide
J-1: bis(2-ethylhexyl) phthalate

According to the evaluation results shown in Tables above, in Comparative Examples 1 to 3 that did not satisfy the requirements of the present disclosure, good performance was not achieved in a manner in which all of the flatness during coating, the post-curing flatness, the copper adhesion, the chemical resistance, and the resolution were well-balanced.

On the other hand, Examples 1 to 73 exhibited excellent performance in all of the flatness during coating, the post-curing flatness, the copper adhesion, the chemical resistance, and the resolution. In the present disclosure, “excellent performance” refers to a performance of “fair” or better in each evaluation item.

### INDUSTRIAL APPLICABILITY

By using the photosensitive resin composition of the present invention, the following can be obtained: a photosensitive resin composition capable of forming a cured relief pattern that has a high in-plane uniformity during spin coating, a low cure shrinkage, a high chemical resistance, a high copper adhesion, and a high resolution; a method of producing a polyimide cured film using the same; and a polyimide cured film. The present invention can be suitably utilized in the field of, for example, photosensitive materials that are useful for the production of electrical/electronic materials of semiconductor devices, multilayer wiring boards, and the like.

1. A negative photosensitive resin composition, comprising:
(A) a polyimide represented by the following Formula (1): 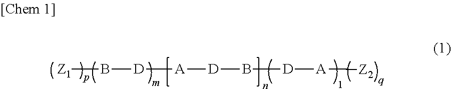
{wherein, A represents a tetracarboxylic dianhydride-derived structure; B represents a diamine-derived structure; D represents an imide structure; Z₁ and Z₂ are optionally the same or different, and each represent a monovalent organic group that contains a photopolymerizable functional group and at least one linking group selected from the group consisting of an ester bond, a urea bond, and an amide bond, which the photopolymerizable functional group exists on an end of Z₁ and/or that of Z₂; land m each represent an integer of 0 or 1, satisfying l+m=1; n represents an integer of 1 to 30; and p and q each represent an integer of 0 to 2, satisfying p+q≥1};
(B) a solvent; and
(C) a photopolymerization initiator.

2. The negative photosensitive resin composition according to claim 1, wherein the amount of an alicyclic structure contained in the polyimide (A) is 1% by mole to 45% by mole.

3. The negative photosensitive resin composition according to claim 1, wherein Z₁ and Z₂ are each a monovalent organic group that contains a linking group of an ester bond and a photopolymerizable functional group.

4. The negative photosensitive resin composition according to claim 1, wherein Z₁ and Z₂ are each a monovalent organic group that contains a linking group of a urea bond and a photopolymerizable functional group.

5. The negative photosensitive resin composition according to claim 1, wherein the polyimide (A) has a molecular weight distribution (Mw/Mn) of 1.0 to 1.8.

6. The negative photosensitive resin composition according to claim 1, wherein the polyimide (A) has a weight-average molecular weight (Mw) of 3,000 to 25,000.

7. The negative photosensitive resin composition according to claim 1, further comprising a polymerizable functional group-containing monomer (D).

8. The negative photosensitive resin composition according to claim 7, wherein the polymerizable functional group-containing monomer (D) contains a monofunctional monomer (D1) and a polyfunctional monomer (D2).

9. The negative photosensitive resin composition according to claim 8, wherein a weight ratio of the D1 and the D2 is 0.01<D1/D2≤1.

10. (canceled)

11. (canceled)

12. (canceled)

13. The negative photosensitive resin composition according to claim 1, further comprising a rust inhibitor (H).

14. (canceled)

15. (canceled)

16. The negative photosensitive resin composition according to claim 1, wherein the structures represented by Z₁ and Z₂ in the Formula (1) are represented by the following Formula (27): 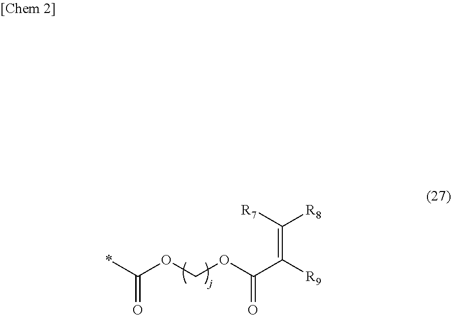
(wherein, R₇, R₈, and R₉ each independently represent a hydrogen atom or a monovalent organic group having 1 to 3 carbon atoms; j represents an integer of 2 to 10; and * represents a binding site with an end of the polyimide (A)).

17. The negative photosensitive resin composition according to claim 1, wherein the structures represented by Z₁ and Z₂ in the Formula (1) are represented by the following Formula (25): 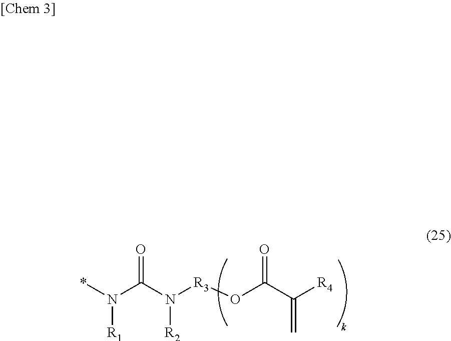
(wherein, R₁ and R₂ are each independently selected from a hydrogen atom and a monovalent organic group having 1 to 3 carbon atoms; R₃ represents an organic group having 1 to 20 carbon atoms, which optionally contains a heteroatom; k represents an integer of 1 or 2; R₄ represents a hydrogen atom or an organic group having 1 to 4 carbon atoms; and * represents a binding site with an end of the polyimide (A)).

18. The negative photosensitive resin composition according to claim 1, wherein the structures represented by Z₁ and Z₂ in the Formula (1) are each at least one selected from the group consisting of the following Formulae (28) to (31): 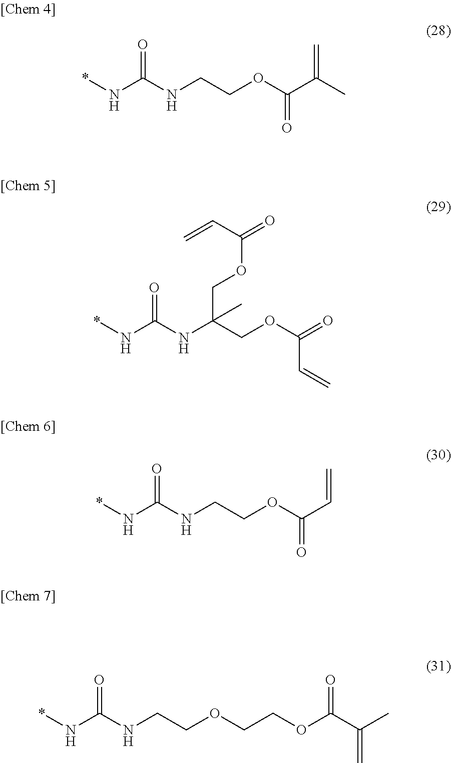 [SMILES: *NC(=O)NCCOC(=O)C(=C)C ; *NC(=O)NC(C)(COC(=O)C=C)COC(=O)C=C ; *NC(=O)NCCOC(=O)C=C ; *NC(=O)NCCOCCOC(=O)C(=C)C]
{wherein, “*” is a binding site with an end of the polyimide (A)}.

19. The negative photosensitive resin composition according to claim 1, wherein A in the Formula (1) has at least one or more of the structures represented by the following Formulae (2) to (9):

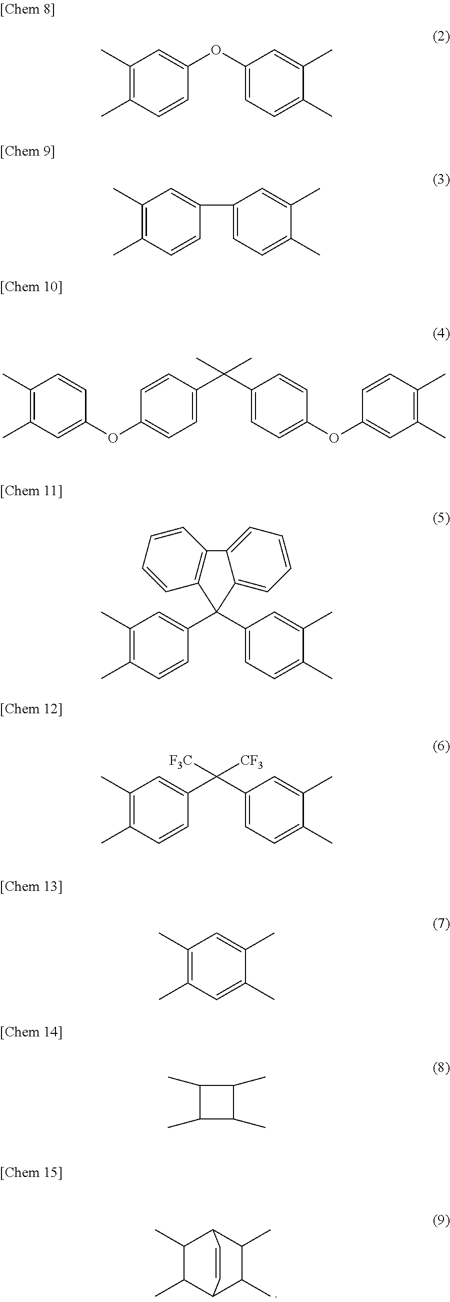

20. The negative photosensitive resin composition according to claim 1, wherein A in the Formula (1) has at least one or more of the structures represented by the following Formulae (8) and (9):

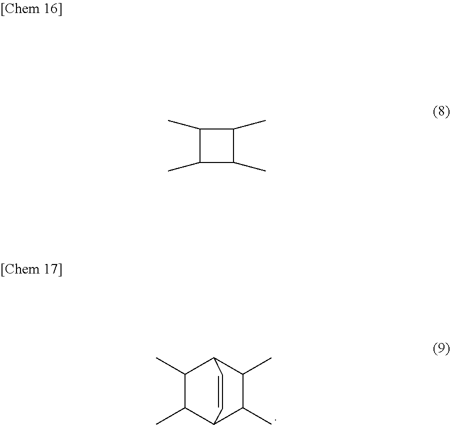

21. (canceled)

22. The negative photosensitive resin composition according to claim 1, wherein B in the Formula (1) has at least one or more of the structures represented by the following Formulae (14), (19), (20), and (21):

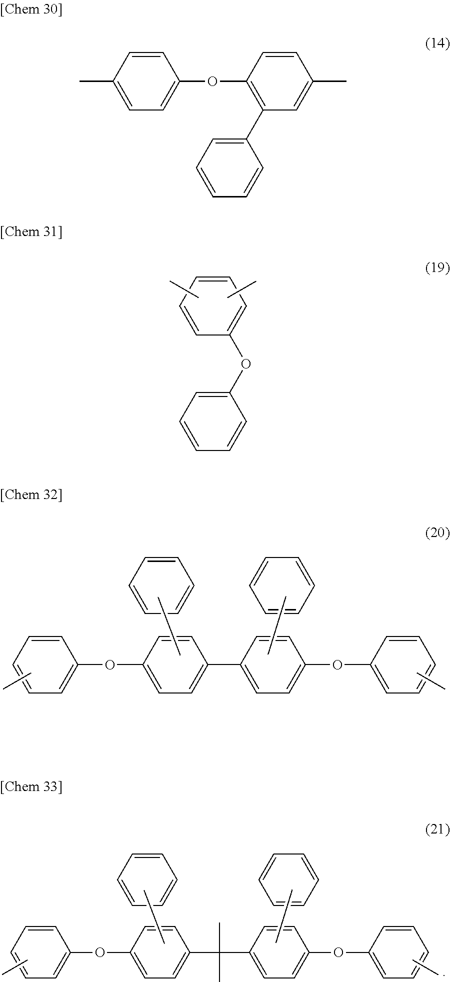

23. (canceled)

24. (canceled)

25. A method of producing a cured relief pattern, the method comprising:
(1) applying the negative photosensitive resin composition according to claim 1 onto a substrate to form a photosensitive resin layer on the substrate;
(2) exposing the photosensitive resin layer;
(3) developing the exposed photosensitive resin layer to form a relief pattern; and
(4) heat-treating the relief pattern to form a cured relief pattern.

26. A method of producing a polyimide having a photopolymerizable functional group on a main chain end, the method comprising:
dehydrating and ring-closing a polyamic acid, which is obtained by reacting a tetracarboxylic dianhydride with a diamine, by a heat treatment to obtain a polyimide having a reactive group on the main chain end; and
reacting the polyimide having a reactive group on the main chain end with a compound having a photopolymerizable functional group on an end,
wherein the compound having a photopolymerizable functional group on an end is at least one type compound selected from the group consisting of isocyanate compounds, chloride compounds, and alcohol compounds.

27. The method of producing a polyimide according to claim 26, wherein
the reactive group is a carboxyl group, and
the compound having a photopolymerizable functional group on an end is an alcohol compound.

28. The method of producing a polyimide according to claim 26, wherein
the reactive group is an amino group, and
the compound having a photopolymerizable functional group on an end is at least one type compound selected from the group consisting of isocyanate compounds and chloride compounds.

29. (canceled)
